(19) United States
(12) Patent Application Publication
(10) Pub. No.: US 2026/0081067 A1
(43) Pub. Date: Mar. 19, 2026

(54) A MECHANICALLY SWITCHED SUPERCONDUCTING FLUX PUMP

(71) Applicant: VICTORIA LINK LIMITED, Wellington (NZ)

(72) Inventors: Rodney Alan Badcock, Wellington (NZ); Christopher William Bumby, Wellington (NZ); Dylan Guja, Wellington (NZ)

(73) Assignee: VICTORIA LINK LIMITED, Wellington (NZ)

(21) Appl. No.: 19/106,872

(22) PCT Filed: Aug. 31, 2023
(86) PCT No.: PCT/IB2023/058594

§ 371 Date: Feb. 26, 2025

(30) Foreign Application Priority Data
Aug. 31, 2022 (AU) 2022902496

(51) Int. Cl. H01F 38/14; H01F 7/20; H02M 7/04

(52) U.S. Cl. CPC H01F 38/14; H01F 7/20; H02M 7/04

(57) ABSTRACT

The invention relates to a device for inducing a current flow in a load, also referred to as a flux pump. The device may comprise a rotor comprising at least one magnetic field generator configured to rotate with the rotor, one or more lengths of superconducting material arranged as an induction coil, a switch, and output terminals configured to connect to a load, the output terminals being connected in parallel with the switch. Rotation of the rotor may move the at least one magnetic field generator relative to the induction coil and switch, such that the magnetic field is periodically applied to the induction coil and switch to induce a current flow in the induction coil through the switch, and to reduce a critical current of the material within the switch, causing the switch to transition from a low-resistance state to a higher-resistance state.

### 1. FIELD OF INVENTION

The present technology relates to the field of superconducting materials, and specifically technologies for increasing current flow in superconducting materials using flux pump technologies. In particular, the present technology relates to mechanically switched superconducting flux pumps. The technology may find particular application in high-power motor applications, magnetic resonance imaging or nuclear fusion. However, this should not be seen as limiting on the present technology.

### 2. BACKGROUND TO THE INVENTION

High temperature superconducting (HTS) materials such as wire or tape generally have a superconducting transition temperature above 77K. Below this temperature, the HTS materials can achieve high magnetic fields due to the extremely low levels of heat dissipation. A key property of superconducting materials is that, in the superconducting state, they have zero or very near zero resistance. This means that, once current is flowing in the superconducting material, it does not decay like in conventional conductors, or at least it decays at a much lower rate.

It is difficult, however, to join HTS materials without using normally conducting (non-superconducting) metal contacts. Where normally conducting contacts are used, significant resistive losses can be introduced into the superconducting circuit, which means current must be continuously injected into the circuit to prevent the current from decaying, which can require a lot of power to continuously operate.

One approach to increasing the current flow within HTS materials is to use a device known as a flux pump. A flux pump can be used to induce a current flow in a superconducting material in a non-contact manner using electromagnetic flux. This allows for current to flow in the HTS circuit without requiring a normally conducting electrical connection.

One form of the flux pump, known as a dynamo flux pump, is described in U.S. Pat. No. 9,972,429. In this dynamo flux pump, a magnetic field is periodically imposed upon a region of HTS material within a superconducting circuit such that magnetic flux vortices are formed within the HTS material. The flux vortices must fully penetrate the HTS material in the direction perpendicular to the desired direction of the net electrical current to be driven around the superconducting circuit. There is a minimum imposed magnetic field intensity at which full flux penetration occurs and this minimum penetration field is referred to as, Bₚₑₙ. While the dynamo configuration generates a net DC transport current, the design generally has high losses since the full current must pass through the dynamic resistance generated by the magnet. In the dynamo flux pump, penetrating flux vortices can be moved through the HTS material by moving an imposed inhomogeneous magnetic field relative to the HTS material in a manner which drags the flux vortices in the direction of movement of the imposed field.

Another type of flux pump is the transformer-rectifier flux pump which generally uses a non-superconducting transformer primary coil magnetically coupled to a superconducting secondary coil. However, the resulting current waveform in the superconducting secondary coil still requires rectification, and there are significant losses due to the currents flowing in the primary coil.

### 3. OBJECT OF THE INVENTION

It is an object of the technology to provide an improved superconducting flux pump. Alternatively, it is an object of the technology to provide a mechanically switched superconducting flux pump. Alternatively, it is an object of the technology to provide an improved device and/or system for inducing a current flow in a load. Alternatively, it is an object of the technology to provide an improved rectifier. Alternatively, it is an object of the technology to at least provide the public with a useful choice.

### 4. SUMMARY OF THE INVENTION

Aspects of the technology relate to electrical devices configured to create a net DC current flow in one or more lengths of superconducting material.

In one aspect of the technology there is provided a device configured to induce a current flow in one or more lengths of superconducting material.

In one aspect of the technology, there is provided a method of inducing a current flow in one or more lengths of superconducting material.

In one aspect of the technology, there is provided a flux pump configured to induce a current flow in one or more lengths of superconducting material.

In one aspect of the technology, there is provided a device for inducing a current flow in a load, which may be referred to as a flux pump. The device may comprise a rotor which comprises at least one magnetic field generator configured to rotate with the rotor. The at least one magnetic field generator may generate a magnetic field. The device may further comprise one or more lengths of superconducting material arranged to provide an induction coil, a switch, and two or more output terminals configured to connect to a load in use, the two or more output terminals being electrically connected in parallel with the switch. Rotation of the rotor may move the at least one magnetic field generator relative to the induction coil and switch, such that: the magnetic field is periodically applied to the induction coil to induce a current flow in the induction coil, at least part of the current flow being configured to flow through the switch; and the magnetic field is periodically applied to the switch and reduces a critical current of the superconducting material within the switch, such that the magnetic field and the current flow within the switch cause the switch to transition from a low-resistance state to a higher-resistance state.

In one aspect of the technology, there is provided a device for increasing current flow in a load. The device may comprise a rotor which comprises at least one magnetic field generator configured to rotate with the rotor. The at least one magnetic field generator may generate a magnetic field. The device may further comprise a stator. The stator may be provided with one or more lengths of superconducting material arranged to provide an induction coil, a switch, and two or more output terminals configured to connect to the load in use, the two or more output terminals being electrically connected in parallel with the switch. In use, the rotor may be configured to rotate relative to the stator, and the at least one magnetic field generator may be configured to periodically apply the magnetic field: to the induction coil to induce a current flow in the induction coil; and to the switch to transition the switch between a low-resistance state and a higher-resistance state for a given current flow within the switch.

In one aspect of the technology, there is provided a device for inducing a current flow in a load, which may be referred to as a flux pump. The device may comprise a rotor which comprises at least one magnetic field generator configured to rotate with the rotor. The at least one magnetic field generator may generate a magnetic field. The device may further comprise a stator. The stator may be provided with an induction coil. The stator may further be provided with a switch configured to transition between a low-resistance state and a higher-resistance state. The stator may further be provided with two or more output terminals configured to connect to the load in use, the two or more output terminals being electrically connected in parallel with the switch. In use, the rotor may be configured to rotate relative to the stator. The at least one magnetic field generator may be configured to periodically apply the magnetic field to the induction coil and switch which: induces a current in the induction coil as it moves relative to the induction coil; and transitions the switch between the low-resistance state and the higher-resistance state for a given current flow. The magnetic field may be applied to the switch with a phase delay relative to the magnetic field being applied to the induction coil.

In one aspect of the technology, there is provided a rectifier. The rectifier may comprise a rotor which comprises at least one magnetic field generator configured to rotate with the rotor. The at least one magnetic field generator may generate a magnetic field. The rectifier may further comprise an induction coil. The rectifier may further comprise a switch comprising one or more lengths of superconducting material. In use the rectifier may be configured to connect to a load, the load being connected electrically in parallel with the switch. In use the rotor may be configured to rotate to move the at least one magnetic field generator relative to the induction coil and switch, to periodically apply the magnetic field to the induction coil and switch such that: a current flow is induced in the induction coil, the current flow having a positive component and a negative component over time, wherein at least part of the current flow is configured to flow through the switch, and the load; and the magnetic field applied to the switch reduces a critical current of the superconducting material within the switch, such that the magnetic field and the current flow within the switch cause the switch to transition from a low-resistance state to a higher-resistance state. The application of the magnetic field to the switch may be synchronised with the positive or negative component of the current flow, such that the switch transitions to the higher-resistance state to increase the amount of current flowing in the load during the positive or negative component, thereby providing a net positive or negative current flow in the load.

In one aspect of the technology, there is provided a system for increasing current flow in a load. The system may comprise a rotor which comprises at least one magnetic field generator configured to rotate with the rotor. The at least one magnetic field generator may generate a magnetic field. The system may further comprise one or more lengths of superconducting material arranged to provide an induction coil and a switch. The system may further comprise a superconducting load connected electrically in parallel with the switch. Rotation of the rotor may move the at least one magnetic field generator relative to the induction coil and switch, such that: the magnetic field is periodically applied to the induction coil to induce a current flow in the induction coil, at least part of the current flow being configured to flow through the switch and the superconducting load; and the magnetic field is periodically applied to the switch and reduces a critical current of the superconducting material within the switch, such that the magnetic field and the current flow within the switch cause the switch to transition from a low-resistance state to a higher-resistance state, thereby effecting the amount of current flowing in the superconducting load.

In certain forms, the magnetic field generator is configured to generate a magnetic field such that a component of the magnetic field is applied to the switch in a direction which is perpendicular to a surface of the superconducting material.

In examples of the technology, the rotor may have a rotational axis about which the rotor rotates in use. For example, the rotor may be provided with a drive shaft, the drive shaft being configured to attach to a drive source in use to rotate the rotor about the rotational axis. For example, the longitudinal axis of the drive shaft may substantially define the rotational axis.

In examples of the technology, the at least one magnetic field generator may be positioned radially outwardly of the rotational axis. For example, the at least one magnetic field generator may be configured to travel in a circular path as the rotor rotates.

In examples of the technology, the one or more magnetic field generators may be provided on a side of the rotor which is closest to the stator.

In examples of the technology, the rotor may comprise at least one support extending outwardly from the rotational axis. For example, the support may be configured to extend substantially perpendicular to the rotational axis. In some examples the support may comprise one or more arms, or a plate to which the at least one magnetic field generator(s) are provided.

In examples of the technology, the rotor may comprise a material having a high magnetic permeability. For example, the rotor may be configured to provide a high magnetic permeability pathway for the magnetic field generated by the magnetic field generator. For example, the rotor may be constructed of a ferromagnetic material, such as iron, or steel.

In examples of the technology, the rotor may be provided with a plurality of magnetic field generators. For example, the rotor may be provided with a first magnetic field generator which is positioned at a first radial distance from the rotational axis, and a second magnetic field generator positioned at a second distance from the rotational axis, the first distance being substantially the same as the second distance.

In examples of the technology, the switch may be positioned at substantially the same radial distance from the rotational axis as one or more magnetic field generators, when measured from the centre point of the switch.

In examples of the technology, the induction coil may be positioned at substantially the same radial distance from the rotational axis as one or more magnetic field generators, when measured from the centre point of the induction coil.

In examples of the technology, the first magnetic field generator may be positioned between 167 and 193 degrees relative to the second magnetic field generator, when measured around the rotational axis.

In examples of the technology, the switch may be positioned between 167 and 193 degrees relative to the induction coil, when measured around the rotational axis. For example the first magnetic field generator may be positioned at approximately 180 degrees relative to the second magnetic field generator, and the switch may be positioned within 167 and 193 degrees relative to the induction coil, such that, as the rotor rotates, and moves the at least one magnetic field generators past the induction coil and switch, the magnetic fields applied to the induction coil and switch are provided with a phase offset of up to 13 degrees.

In examples of the technology, where more than two magnetic field generators are used, the magnetic field generators may be evenly spaced around the rotor. For example, the magnetic field generators may be provided in pairs, such as two, four, six, or eight magnetic field generators. Wherein each of the pairs of magnetic field generators may be positioned substantially diametrically opposite to one another. In other examples, each of the pairs of magnetic field generators may be positioned within 167 degrees and 193 degrees of one another relative to the rotational axis.

In examples of the technology, the flux pumps and rectifiers described herein may further comprise a stator.

In examples of the technology, the stator may comprise a material having a high magnetic permeability.

For example, the stator may be configured to provide a high magnetic permeability pathway for the magnetic field generated by the magnetic field generator. For example, the stator may be constructed of a ferromagnetic material, such as iron, or steel.

In examples of the technology, one or more magnetic field generators may comprise a permanent magnet. For example, the one or more magnetic field generator may comprise samarium cobalt (SmCo), Alnico or neodymium iron boron (NdFeB). In other examples of the technology the one or more magnetic field generator may comprise an electromagnet.

In examples of the technology, the one or more lengths of superconducting material may comprise a high-temperature superconductor. For example, the high temperature superconducting material may comprise a rare-earth Barium Copper Oxide (ReBCO) such as a ReBCO tape.

In examples of the technology, the stator may comprise one or more arms. For example, the stator may comprise a stator base, and the one or more arms may extend upwardly from the stator base towards the rotor. For example, the stator arms may be substantially perpendicular to the stator base.

In examples of the technology, the induction coil may comprise less than one turn of the one or more lengths of superconducting material. For example, the induction coil may comprise less than or equal to one turn, such as a quarter turn, or a half-turn of superconducting material. In other examples of the technology the induction coil may comprise one or more turns of the one or more lengths of superconducting material (including non-integer numbers of turns). For example, the one or more lengths of superconducting material may be looped around one or more of the arms of the stator. For example, the induction coil may comprise, one and a half turns, or two or more turns of the one or more lengths of superconducting material.

In examples of the technology, the induction coil may comprise a section of superconducting material arranged in a substantially arcuate path, the focus of the arcuate path defining a centre of the induction coil, and wherein the at least one magnetic field generator has a radial distance from the rotational axis which is substantially the same as the radial distance of the centre of the induction coil from the rotational axis.

In examples of the technology, any one or more of the stator arms may be substantially cylindrical. For example, the stator arm may have a radius which is greater than or equal to a minimum bend radius of the superconducting material. For example, any one or more of the stator arms may have a radius of greater than or equal to 50 mm.

In examples of the technology, the switch may be referred to as a “J_{c}(B) switch”. In other words, the switch may be structured or arranged such that the magnetic field generated by the magnetic field generator influences the maximum critical current of the one or more lengths of superconducting material to thereby transition the superconducting material between a first, low-resistance state and a second, higher-resistance state for a given current through the switch. For example, the switch may be configured or arranged such that at least a portion of the magnetic field applied by the magnetic field generator is perpendicular to a surface of the one or more lengths of superconducting material.

In one example of the technology the switch may be located on the same stator arm as the induction coil. While in other examples of the technology the switch may be located on an opposing stator arm to the induction coil, such as a stator arm which is located within 167 degrees and 193 degrees relative to the stator arm comprising the induction coil.

In examples of the technology, the flux pump may comprise a plurality of induction coils, and/or a plurality of switches.

In examples of the technology, the switch(es) may be connected electrically in parallel with the output terminals or a load. For example, the load may comprise a circuit or a loop of superconducting material. For example, the loop of superconducting material may comprise 10 or more turns of a high-temperature superconductor.

In examples of the technology, the switch may be positioned on one or more of the stator arms, for example on a stator arm between the stator and the rotor. For example, at least a portion of the switch may be configured to extend in a direction which is substantially perpendicular to the magnetic flux generated by the magnetic field generator(s).

In examples of the technology, the switch may be positioned between a stator arm and a field spreader. For example, the field spreader may be configured to generate or otherwise cause a homogenous magnetic field to act upon at least a portion of the switch, such as the one or more lengths of superconducting material of the switch. For example, the field spreader may comprise a material having a high magnetic permeability, such as a ferromagnetic material.

In examples of the technology, the field spreader may be dimensioned to have substantially the same width as the magnetic field generator when measured in a direction radially outwardly of the rotational axis.

In examples of the technology, the field spreader may be positioned substantially centrally on the top of the one or more arms of the stator.

In examples of the technology, the distance from any edge of the field spreader to the edge of the stator arm on which it is located may be less than the width of the magnetic field generator.

In examples of the technology, any one or more of the induction coil, switch and load or terminals may be constructed from a single continuous length of superconducting material. For example, a high-temperature superconducting tape. In other words, the superconducting material may be configured such that there are no joints between any one or more of the induction coil, switch, and load or terminals.

In other examples of the technology, any one or more of the induction coil, switch and load or terminals, may be connected using a join. For example, the join may be a normally conducting join as should be familiar to those skilled in the art.

In examples of the technology, the one or more lengths of superconducting material may be positioned within a cryostat. For example, the stator may be positioned within the cryostat. For example, the cryostat may comprise a cryostat refrigeration system as should be familiar to those skilled in the art.

In examples of the technology, the cryostat refrigeration system may comprise a liquid cryogen operable to cool by latent heat of evaporation, and/or a thermo-mechanical refrigerator. For example, liquid nitrogen may be used.

In examples of the technology, the rotor may also be positioned within the cryostat. For example, a drive means may be provided externally to the cryostat, which is operatively connected to the rotor, by way of a drive shaft which extends through a wall of the cryostat.

In examples of the technology, the flux gap, or otherwise separation between the magnetic field generator and the stator, may be less than 6 mm, for example the flux gap may be 1 mm or less.

It should be appreciated that the present technology may provide any one or more of a number of advantages including:
The ability to have a switched rectifier operating across a cryostat wall without penetrating the wall;
More efficient flux pump technologies;
Flux pump technologies operable within or at least partially within a cryostat;
Lower cooling requirements in comparison to transformer-based flux pump technologies;
Greater efficiency than dynamo based flux-pump technologies; and
Automatic regulation of the induced current in the superconducting material, i.e. regulation without requiring any control circuitry.

Further aspects of the technology, which should be considered in all its novel aspects, will become apparent to those skilled in the art upon reading of the following description which provides at least one example of a practical application of the technology.

### 5. BRIEF DESCRIPTION OF THE DRAWINGS

One or more embodiments of the technology will be described below by way of example only, and without intending to be limiting, with reference to the following drawings, in which:

FIG. 1 shows an exemplary electric-field versus current graph for a high-temperature superconductor;

FIG. 2 shows an exemplary graph indicating the effect of applied magnetic field to the critical current of a high-temperature superconductor;

FIG. 3 shows a simplified schematic diagram of a superconducting flux pump in accordance with the present technology;

FIG. 4A shows a first example of a superconducting flux pump in accordance with the present technology;

FIG. 4B shows an alternative superconducting flux pump in accordance with the present technology;

FIG. 5 shows an alternative superconducting flux pump in accordance with the present technology;

FIG. 6 shows an exemplary curve showing experimental performance of the flux pump of FIG. 5 increasing the current flow in a high-temperature superconductor over time;

FIG. 7A shows a first example of how a power supply has traditionally been used to increase the current flow in a superconducting coil positioned within a cryostat;

FIG. 7B shows a second example of how a superconducting flux pump can be used to increase the current flow in a superconducting coil positioned within a cryostat;

FIG. 7C shows a third example of how a superconducting flux pump can be used to increase the current flow in a superconducting coil positioned within a cryostat;

FIG. 8 shows a superconducting flux pump arrangement in accordance with one example of the present technology;

FIG. 9 shows one example of a switch in accordance with the present technology;

FIG. 10 shows a simplified schematic diagram of a superconducting flux pump with a series shunt resistance;

FIG. 11A shows a magnetic field diagram for a flux pump in accordance with the present technology;

FIG. 11B shows a close-up view of the field spreader within the magnetic field diagram of FIG. 11A;

FIG. 12A shows an exemplary stator in which the switch position is adjustable in accordance with the present technology;

FIG. 12B shows a switch holder which can be adjustably positioned on the stator in order to change the phase relationship between the induction coil and switch, in accordance with the present technology;

FIG. 12C shows a graph of the current versus phase relationship between the induction coil and switch in accordance with the adjustable design of FIGS. 12A and 12B;

FIG. 12D shows a graph of the current versus phase relationship between the induction coil and switch in accordance with a further embodiment of the present technology;

FIG. 13 shows a side schematic view of a flux pump within a housing in accordance with the present technology;

FIG. 14A shows a schematic view of a Jc(B) switch arrangement in accordance with the present technology;

FIG. 14B shows a schematic view of a bifilar Jc(B) switch arrangement in accordance with the present technology;

FIG. 14C shows a schematic view of an alternative bifilar Jc(B) switch arrangement in accordance with the present technology; and

FIG. 15 shows a graph summarising the real-world operating voltages of a flux pump constructed in accordance with the present technology.

### 6. DETAILED DESCRIPTION OF PREFERRED EMBODIMENTS OF THE INVENTION

### 6.1. Superconductivity Principles

A superconductor or superconducting material is a material that exhibits zero electrical resistance below a certain temperature known as the critical temperature, T_{c}. This zero electrical resistance state is often referred to as a superconducting state. This lack of resistance is the result of a phenomenon known as the Meissner Effect, which is the complete expulsion of any magnetic field from the superconductor. Superconductors are perfect diamagnetic materials up until a certain magnetic field strength known as the critical field, B_{c}. At this point the superconductor cannot keep the magnetic field out, and thus the magnetic field enters the superconductor, causing flux flow within the superconductor, which transitions the superconductor from the superconducting state to a normally conducting state, or a state which no longer has zero electrical resistance. This critical field also implies that there is a limit to the current that the superconductor can carry, known as the critical current, I_{c}.

There are two types of superconductors, named type I and type II. Type I superconductors are typically pure metals and behave as described above. Type II superconductors behave differently. Type II superconductors allow some magnetic field to penetrate at a critical field H_{c1}<H_{c} without transitioning out of the superconducting state. Because of this, type II superconductors can carry much more current than type I superconductors, making them useful for practical applications.

The critical temperature for a superconductor is conventionally defined as the temperature below which the resistivity of the superconductor drops to zero or near zero. In other words, a superconductor is said to be in its superconducting state when the temperature of the superconductor is below the critical temperature and in a non-superconducting state when the temperature is above the critical temperature. Many superconductors have a critical temperature which is near absolute zero; for example, mercury is known to have a critical temperature of 4.1K. It is however also known that some materials can have critical temperatures which are much higher such as 30K to 125K; for example, magnesium diboride has a critical temperature of approximately 39K, while yttrium barium copper oxide (YBCO) has a critical temperature of approximately 92K. These superconductors are often generally referred to as high-temperature superconductors (HTSs).

### 6.1.1. Critical Current

The critical current for a high-temperature superconductor wire or tape is conventionally defined as the current flowing in a superconductor wire/tape which results in an electric field drop along the wire of 100 μV/m (=1 μV/cm). The critical current is a function of both the superconducting material used, and the physical arrangement of the superconducting material. For example, a wider tape/wire may have a higher critical current than a thinner tape/wire constructed of the same material. Nevertheless, throughout the specification, reference to the critical current of the superconductor/superconducting material is made to simplify the discussion.

In a superconductor, if the current I is approximately equal to the critical current I_{c}, the resistance of the superconductor is non-zero, but small. However, if I is much larger than the critical current I_{c}, the resistance of the superconductor becomes sufficiently large to cause heat dissipation which can heat the superconductor to a temperature above its critical temperature, which in turn causes it to no longer be superconducting. This condition is sometimes referred to as a “quench” and can be damaging to the superconductor itself.

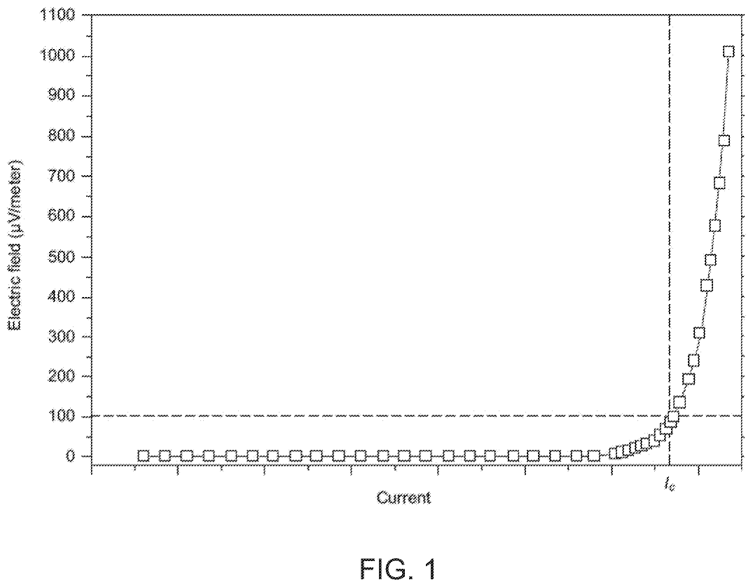

FIG. 1 shows an exemplary plot depicting the internal electric-field versus current curve for a high-temperature superconductor. The electric field shown in this plot is related to resistance via the following equation:

$$E = \frac{IR}{L}$$

where:
E is the electric field;
I is the current through the superconductor;
R is the resistance of the wire; and
L is the length of the wire.

Accordingly, the plot of FIG. 1 is related to the resistance per-unit length for the superconductor and, because the curve depicted is non-linear, the resulting resistance for the superconductor is non-linear with current.

In FIG. 1 it can be seen that the electric field strength in the superconductor is substantially zero below the critical current I_{c} for the superconductor. As the current in the superconductor approaches the critical current, the electric field in the superconductor starts to increase. At the critical current, the electric field in the superconductor is 100 μV/m. Further increasing the current in the superconductor above the critical current results in rapid increases in the electric-field strength in the conductor.

The transition from the superconducting to the normal state in HTS materials, such as is shown in FIG. 1, can be described by an empirical law known as the E-J power law:

$$E = {{E}_{0} ( \frac{J}{{J}_{c}} )}^{n}$$

where E is the electric field in the conductor, J is the current density, and n is an experimentally defined unitless parameter which governs the steepness of the transition. In most superconductors, n has a value between 25-30. The critical current density J_{c} is defined by some arbitrarily chosen threshold field E₀, which may be 100 μV/m (=1 μV/cm) as explained above.

In this specification reference may be made to the relative resistances of a superconducting material and components comprising a superconducting material. More particularly, the specification refers to a superconducting material being in a low-resistance or higher-resistance state. It will be appreciated that, when in a superconducting state, superconducting materials can have a resistance which is zero or substantially zero, and as such these resistances are often expressed in terms of the electric field present across the superconducting material for a given current. Nevertheless, throughout the present specification, reference is made to relative resistances, for example low-resistance and higher-resistance states of the superconducting material, in order to simplify the discussion.

The term ‘low-resistance state’ may refer to when the superconducting material has a resistance that is close to or substantially zero in the superconducting state, or when the material has a low resistance in a partially superconducting state. The term ‘higher-resistance’ state refers to a state in which the superconducting material has a resistance that is substantially greater than the resistance in the low resistance state, for example a substantially non-zero resistance or a resistance that is close to zero but substantially greater than the resistance in the low-resistance state. For the avoidance of doubt, a higher-resistance state as referred to in this specification may, unless the context clearly indicates otherwise, include a superconducting state.

Similarly, where in this specification reference is made to a superconductor being in a higher-resistance state as a result of a current carried by the superconductor exceeding the critical current, it should be understood that, unless the context clearly indicates otherwise, the higher-resistance state may also be achieved if the current carried by the superconductor approaches or is substantially equal to the critical current.

In describing the technology in this specification, material and components comprising the material are referred to as “superconducting”. This term is commonly used in the art for such materials and should not be taken to mean that the relevant material is always in a superconducting state. Under certain conditions the material and components comprising the material may not be in a superconducting state. That is, the material may be described as being superconductive but not superconducting.

### 6.1.2. Superconducting Materials

Certain forms of the present technology may comprise a variety of types of superconducting material. For example, forms of the technology may comprise high-temperature superconducting (HTS) materials. Exemplary HTS materials suitable for use in the forms of technology described include copper-oxide superconductors, for example a rare-earth barium copper oxide (ReBCO) such as yttrium barium copper oxide, gadolinium barium copper oxide or bismuth strontium calcium copper oxide (BSCCO) superconductors, and iron-based superconductors. BSCCO superconductors typically have a strong interdependence between critical current and an applied magnetic field, which may make them particularly suitable for some forms of the present technology. Other types of superconductors may be used in other forms of the technology.

While forms of the technology will be described in relation to high-temperature superconductors, it should be understood that other forms of the technology may use other types of superconductor, for example low-temperature superconductors, in their place.

### 6.1.3. Effect of Magnetic Field on Superconductors

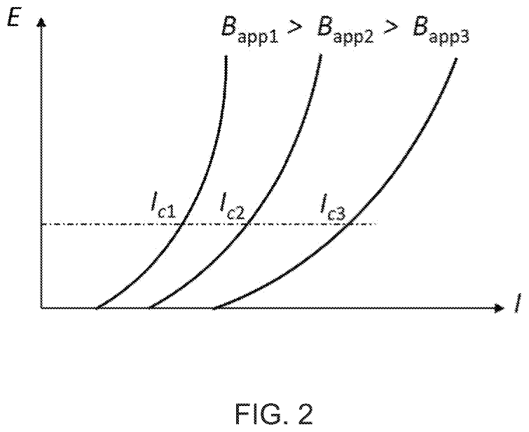

The critical current in a superconductor is dependent on the external magnetic field applied to the superconductor. More particularly, the critical current decreases as a higher external magnetic field is applied to the superconductor, up to the value of the critical field, above which the superconductor is no longer in the superconducting (low resistance) state. This relationship is shown in FIG. 2, which is an illustration of graphs of electric field against current for a superconducting material when three external magnetic fields of different magnitude are applied. The highest magnitude of external magnetic field, Bₐₚₚ₁, results in the lowest critical current, I_{c1}. In some forms, the external magnetic field to achieve this effect may be applied perpendicular to the surface of the length of superconductor in which the critical current is reduced, or suppressed. The applied magnetic field may be in one direction only, which may be referred to as a DC field, as compared to a time-varying magnetic field whose direction cycles, for example sinusoidally, which may be referred to as an AC field.

For all superconductors, the critical current drops off sharply with only a small applied magnetic field. This means that a small change in the applied magnetic field can result in a large change in the critical current. This relationship is dependent on the superconducting material and the way the length of superconducting material that carries current was manufactured.

It should be appreciated that this mechanism to reduce or suppress the critical current by applying an external magnetic field, e.g. a DC field, is different from the phenomenon of dynamic resistance. This occurs when a superconductor is exposed to a time-varying magnetic field while carrying a DC transport current. This creates a DC electrical resistance in the superconductor, which may be sufficiently large that the superconductor switches into a higher-resistance state.

### 6.1.4. Superconducting Switches

Throughout the present specification, reference will be made to the relative resistances of a superconducting switch and components thereof. In general terms, a superconducting switch is a switch incorporating one or more superconducting materials that can transition between a low-resistance state and a higher resistance state as described herein. These may not be open/closed circuit states as would be common for traditional normally conducting switches, and typically, even in the higher resistance state, the resistance may be considered to be low by the standards of a normally conducting switch, e.g. a few ohms or less.

It should be appreciated by those skilled in the art that superconducting materials when in a superconducting state can have a resistance which is zero or substantially zero, and as such these resistances are more commonly expressed in terms of the electric field present across the superconducting material for a given current. Nevertheless, throughout the present specification, reference has been made to relative resistances, low-resistance and higher-resistance states in order to simplify the discussion.

### 6.2. Mechanically Switched Flux Pumps

### 6.2.1. Principle of Operation

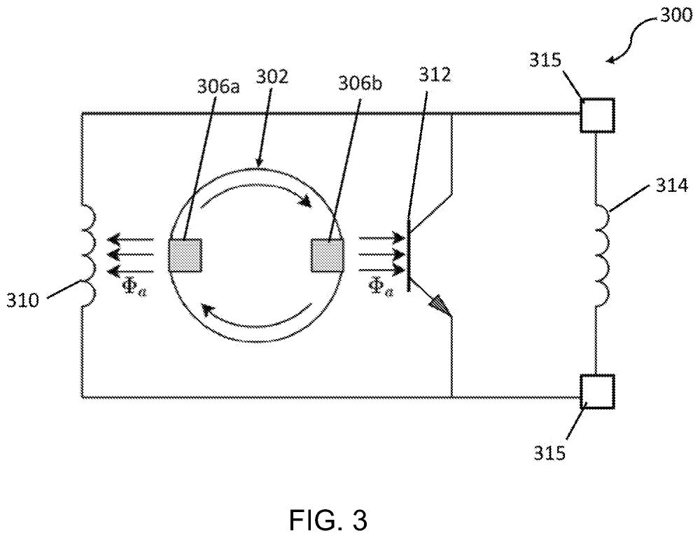

FIG. 3 shows an example of a mechanically switched flux pump 300 in accordance with one form of the present technology. In broad terms, the flux pump 300 comprises a rotor 302 which is configured to rotate around a rotation axis in use. The rotor 302 includes one or more magnetic field generators 306, each configured to generate a magnetic field, such as a permanent magnet or an electromagnet.

In use, the rotation of the rotor 302 moves the one or more magnetic field generators 306 past an induction coil 310 and a switch 312, to periodically apply a magnetic field to the induction coil 310 and switch 312, for example the one or more magnetic field generators may move in a substantially circular path. The magnetic fields generated by the magnetic field generators 306 are configured to induce a current flow in the induction coil 310 and apply a magnetic field to the switch 312, for example a magnetic field which has a component perpendicular to a surface of the switch, to thereby lower the critical current of the switch because of the effect described earlier. The lower critical current of the switch 312 when the magnetic field is applied means that, for a given current flow, the switch 312 has a higher-resistance, or is in a high-resistance state when compared to when the magnetic field is not applied to the switch. Throughout the present specification, reference to the switch transitioning from a low-resistance state to a higher-resistance state should be understood to refer to the relative resistances when a given current is flowing through the switch. For example, the current may be equal to or less than the current induced in the induction coil 310. In some forms, the switch 312 is in a superconducting state when in the higher-resistance state. It should be understood that this may be the case for any of the forms of technology, even if not explicitly stated.

In the example of FIG. 3 a load 314 is provided which is connected electrically in parallel with the switch 312. The load may preferably comprise a superconducting coil, however this should not be seen as limiting on the technology, and the load may be any suitable component or circuit which is placed in parallel with the switch 312. In some aspects of the technology the flux pump 300 described herein, may be provided with two or more output terminals 315 which are configured to configured to connect to a load 314 in use, the two or more output terminals 315 being electrically connected in parallel with the switch.

In the example shown two magnetic field generators 306a, 306b are provided, each magnetic field generator is positioned diametrically opposite or approximately 180 degrees relative to each other on the rotor 302. The induction coil 310 and switch 312 are positioned such that, during rotation of the rotor 302, the first magnetic field generator 306a passes by the induction coil 310 so that its magnetic field is applied to the induction coil 310, and induces a current flow within the induction coil 310. At approximately the same time, the second magnetic field generator 306b, passes by the switch 312 so that its magnetic field is applied to the switch 312 and the magnetic field generated by the second magnetic field generator 306b lowers the critical current of the switch, which transitions the switch from a low resistance state to a higher-resistance state for a given current flow as described herein. Similarly, after further rotation of the rotor 302, as the second magnetic field generator 306b passes the induction coil 310, it induces a current flow in the induction coil 310, and the first magnetic field generator 306a passes by the switch and the magnetic field generated by the first magnetic field generator 306a transitions the switch from a low resistance state to a higher-resistance state as described herein. In between these states, the first and second magnetic field generators 306a and 306b are further away from the induction coil 310 and switch 312 and therefore their magnetic fields may not act to induce a current in the induction coil 310, or to lower the critical current of the switch 312, or at least do so to a lesser extent than when the magnetic field generators are proximate the induction coil and switch. Further rotation of the rotor 302 causes periodic cycling of the described behaviours. For example, the induction coil 310 and the switch 312 may be positioned, relative to the rotor 302, substantially diametrically opposite each other.

Accordingly, with a single 360° rotation of the rotor 302, current is induced in the induction coil 310 twice, and the switch 312 transitions from the low-resistance state to the higher-resistance state in a synchronised manner each time. The use of two magnetic field generators 306a, 306b in FIG. 3 should not be seen as limiting on the technology, and any number of magnetic field generators 306 may be used. It can be advantageous in some examples of the technology to use an even number of magnetic field generators such that each magnetic field generator 306 can have a corresponding magnetic field generator positioned substantially opposite to, such as 180° opposite to another one of the magnetic field generators. It should be appreciated that the greater the number of magnetic field generators used, the greater the number times current is induces in the induction coil 310, and subsequently, the greater number of times the switch is transitioned from the low-resistance state to the higher-resistance state per 360-degree rotation of the rotor.

By adjusting the timing and duration of the switch 312 transitioning from the low-resistance state to the higher resistance state, it is possible to influence the current flowing in the load 314, and thereby regulate the current flow such that the load 314 has a net DC current flow, thereby allowing for an increase in the load 314 current on a cycle-by-cycle basis.

The transitioning of the switch 312 from the low resistance state to the higher resistance state in phase with the induced current in the induction coil 310 results in an increased current flow from the induction coil 310 being transferred to the load 314 during the higher-resistance state versus the current flow to the load in the low-resistance state. This is due to the load 314 being electrically connected in parallel with the switch 312, and the ratio of the current flows between the load 314 and the switch 312 being dependent on the relative impedances or resistances of the load 314 to the switch 312.

It should be appreciated that the movement of the magnetic field generator 306 relative to the induction coil 310 applies a changing magnetic field to the induction coil 310 which results in a current flow in the induction coil 310. The current flow in the induction coil 310 generally has a positive component and a negative component. In other words, the current flow in the induction coil can oscillate between a positive current flow and a negative current flow over time. Accordingly, by transitioning the switch 312 to the higher-resistance state during the positive current flow, or negative current flow, it may be possible to provide a net positive or negative current flow in the load. In other words, the relative timing of the switch transitioning to the induced current pulse, can be adjusted such that the higher resistance state substantially corresponds to the positive component of the current flow induced in the induction coil, and the lower resistance state substantially corresponds to the negative current flow induced in the induction coil 310.

In the examples described herein, the induction coil 310 and switch 312 are provided by one or more lengths of superconducting material, such as a high-temperature superconductor as will be discussed herein. In particular, the use of one or more lengths of superconducting material may advantageously provide improved efficiency in superconducting flux pump technologies. However, this should not be seen as limiting on the technology, and in other examples, any one or more components of the present technology may be provided with normally conducting equivalents.

### 6.2.1. Magnetic Flux Coupling

One method of increasing the induced current in the induction coil 310 is to increase the strength of the magnetic field applied to the induction coil 310. One way of achieving this is to couple the magnetic field to the induction coil using a material with high magnetic permeability, such as by using a ferromagnetic material such as steel.

Similarly, for various types of superconducting switch mechanism, such as those described here, it can be advantageous to increase the strength of the magnetic field acting upon the length of superconducting material as this may cause any one or more of: a greater suppression of the critical current, an increase the current induced in the induction coil 310 and/or an increase in the resistance of the switch 312 in the higher-resistance state.

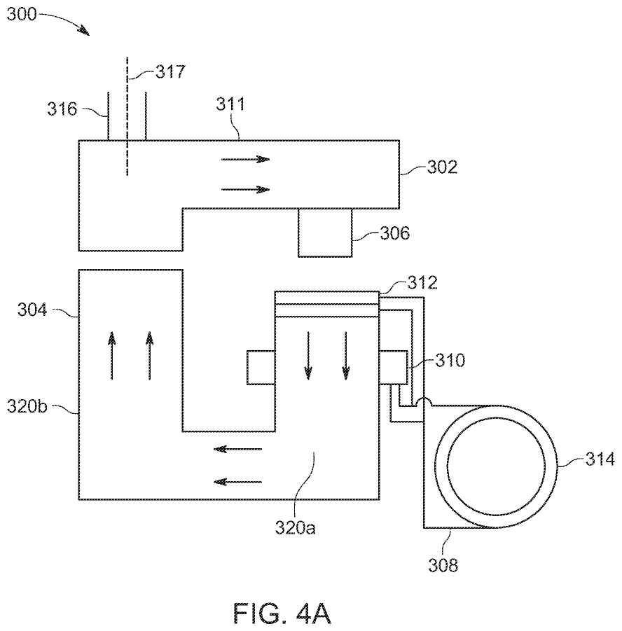

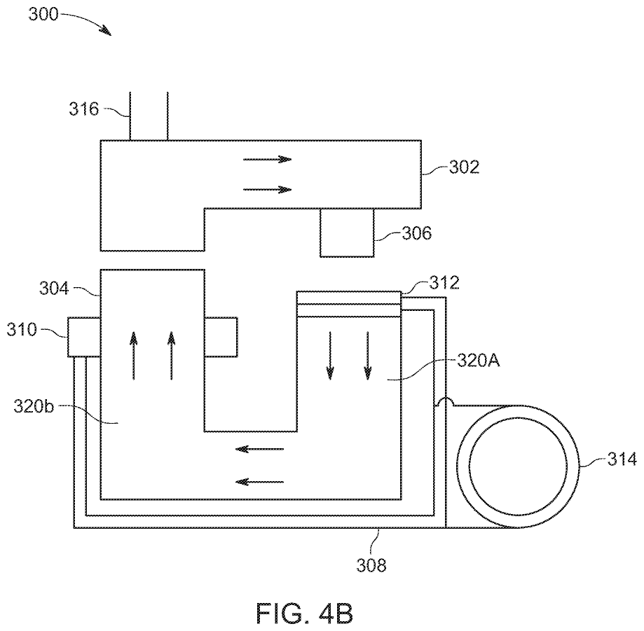

FIG. 4A shows an example of a flux pump 300 according to one form of the technology which comprises a ferromagnetic stator 304, and a ferromagnetic rotor 302. The stator comprises a first arm 320a to which the induction coil 310 and switch 312 are provided. The stator also includes a second arm 320b which acts as a magnetic return path to minimise the total air-gap between the rotor 302 and stator 304.

The stator 304 is provided with one or more lengths of superconducting material 308 which is configured to provide the induction coil 310, and the switch 312. In the illustrated example the superconducting material 308 also provides a superconducting load 314 in the form of a load coil, however, this should not be seen as limiting on the technology. For example, two or more output terminals may be provided in place of the load as described herein.

The rotor 302 may comprise a drive shaft 316, which in use is connected to a drive source such as a motor to rotate the rotor 302. Therefore, in the illustrated example, the longitudinal axis of the drive shaft 316 defines a rotation axis 317 for the rotor 302.

The flux pump 300 of FIG. 4A operates by rotating the rotor 302 to move the magnetic field generators 306, past one or more stator arms 320a, 320b. This movement generates a changing magnetic field within the stator 304 which passes through the loop of the induction coil 310 and the switch 312 respectively.

In the illustrated example the drive shaft 316 is provided in line with the second arm 320b of the rotor. In other words, the axis of rotation 317 is aligned with the second arm 320b such that the second arm remains adjacent to the rotor in use. In this way the present technology, can be configured to generate a changing magnetic field in the stator as the magnetic field generator 306, passes by the first arm 320a only.

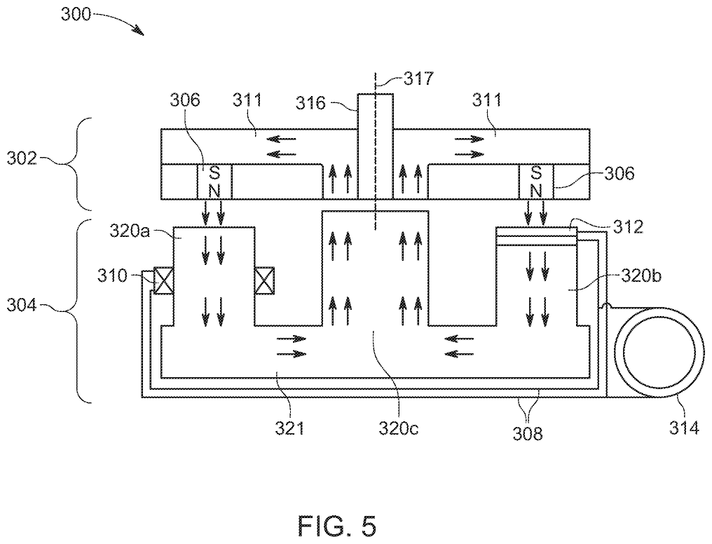

It should be appreciated that, as illustrated, the rotor is asymmetric about the rotational axis 317 which may result in vibrations or oscillations during use. Accordingly, in some examples of the technology the rotor may be provided with a substantially symmetric construction about the rotational axis, such as in the example of FIG. 5.

The magnetic field generator 306 may be positioned on the side of the rotor 302 nearest the stator 304. The magnetic field generator 306 may be provided at a radial distance from the rotation axis 317, so that the magnetic field generator travels through an arcuate or circular path in use.

In FIG. 4A, the magnetic field generators are attached to the rotor by way of one or more support members 311. In the illustrated example the support member 311 comprise a plate or substantially circular support. For example, the support member 311 may have a substantially circular cross-section, when cross-sectioned in a plane perpendicular to the rotation axis 317 or otherwise be a substantially circular plate. Use of a substantially circular support member may advantageously result in decreased drag or air turbulence, particularly in example of the technology where the rotor is located within a cryostat as described herein. However, this should not be seen as limiting and in other examples the support members 311 may comprise arms or elongate structures which support the corresponding magnetic field generators.

It may be advantageous for the mid-point of each arm 320a, 320b, to have a radial distance from the rotation axis 317 which is substantially equal to the radial distance of the magnetic field generator 306, to provide a short magnetic path between the magnetic field generator 306 and stator 304.

In use the flux pump 300 of FIG. 4A operates by rotating the rotor 302, to move the magnetic field generator 306 in an arcuate path past one or more arms 320a, 320b of the stator. The movement of the magnetic field generator past the arms 320a, 320b generates a changing magnetic field in the stator 304, which in turn generates a current flow in the induction coil 310 and causes the switch to transition between a low-resistance state and a higher-resistance state.

In FIG. 4A the switch 312 and induction coil 310 are provided on a single arm 320a of the stator. In other examples of the technology, the switch and/or induction coil may be positioned at any location on the stator. For example, the switch may be provided to a portion between the arms 320a, 320b of the stator 304, for example a midpoint between the arms. Similarly, the induction coil may be provided on either arm, or around the section of the stator joining the arms such as the stator base 321.

For example, FIG. 4B shows an alternative flux pump 300 according to another form of the technology in which the induction coil 310 is provided on a second arm 320B of the stator 304.

FIG. 5 shows a further example of a flux pump 500 according to another form of the technology, which comprises a ferromagnetic stator 304, and a ferromagnetic rotor 302. The stator comprises a first arm 320a to which the induction coil 310 is provided (for example the induction coil 310 may be wound around the first arm 320a), and a second arm 320b to which the switch 312 is provided (for example the switch may be positioned on the top of the second arm 320b). The stator may also include a third, central arm 320c in order to minimise the total airgap between the rotor 302 and stator 304.

The stator 304 may be provided with one or more lengths of superconducting material 308 which is configured to provide the induction coil 310, and the switch 312. In the illustrated example the superconducting material 308 also provides a superconducting load 314 in the form of a load coil, however, this should not be seen as limiting on the technology.

The flux pump 300 of FIG. 5 operates by rotating the rotor 302 to move the magnetic field generators 306, past one or more stator arms 320a, 320b to provide the magnetic fields generated by the magnetic field generators 306 to the induction coil 310 and switch 312 respectively.

For example, the rotor 302 may comprise a drive shaft 316, which in use is connected to a drive source such as a motor to rotate the rotor 302. Therefore, in the illustrated example, the longitudinal axis of the drive shaft 316 defines a rotation axis 317 for the rotor 302.

The magnetic field generators 306 may be positioned on the side of the rotor 302 nearest the stator 304. The magnetic field generators 360 may be positioned at a radial distance from the rotation axis 317, so that each magnetic field generator travels through an arcuate or circular path in use. It can be advantageous for each of the one or more magnetic field generators to follow substantially the same arcuate or circular path in use. For example, each of the one or more magnetic field generators may have substantially the same radial distance from the rotation axis 317.

In FIG. 5, the magnetic field generators are attached to the rotor by way of support members 311. In the illustrated example the support members 311 can be considered arms of the rotor. For example, each of the support members may be independent elongate structures which support the corresponding magnetic field generators. In other examples of the technology, the support member 311 may have a substantially circular cross-section, when cross-sectioned in an axis perpendicular to the rotation axis 317 or otherwise be a substantially circular plate. Use of a substantially circular support member may advantageously result in decreased drag or air turbulence, particularly in example of the technology where the rotor is located within a cryostat as described herein.

It can be advantageous for the mid-point of each arm 320a, 320b, to have a radial distance from the rotation axis 317 which is substantially equal to the radial distance of the magnetic field generator 306, to provide a short magnetic path between the magnetic field generator 306 and stator 304.

In use the flux pump 300 of FIG. 5 operates by rotating the rotor 302, to move the one or more magnetic field generators 306 in an arcuate path past one or more arms 320a, 320b of the stator. The movement of the magnetic field generator past the arms 320a, 320b generates a changing magnetic field in the stator 304, which in turn generates a current flow in the induction coil 310. The changing magnetic field in the stator 304 further acts on the switch 312 which transitions from a low-resistance state to a higher resistance state as described herein.

In the illustrated example, two magnetic field generators are used, and the magnetic field generators are configured such that as a first magnetic field generator 306a, passes over a first stator arm 320A, the second magnetic field generator passes over a second arm 320B. Each magnetic field generator generates a changing magnetic field as indicated by the arrows in FIG. 5. Accordingly, the changing magnetic field used to induce a current flow in the induction coil 310 may be different to the magnetic field used to transition the switch from the low-resistance state to the higher-resistance state.

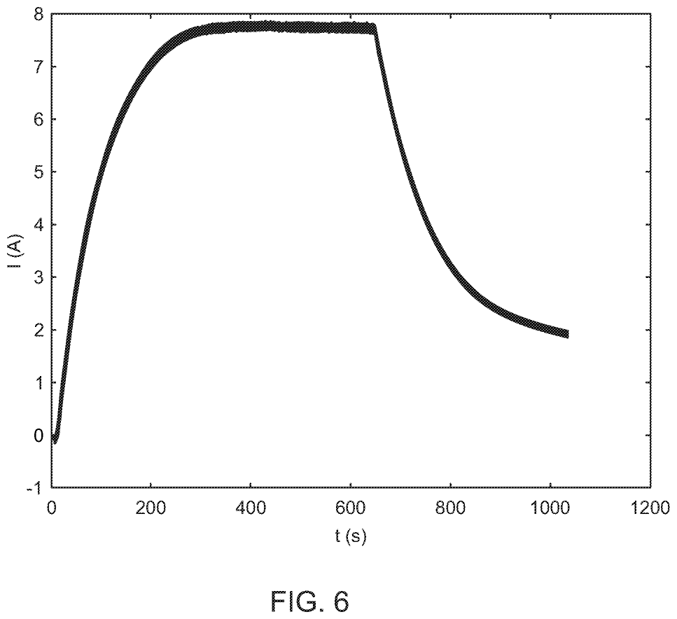

FIG. 6 shows a measured output of a flux-pump prototype constructed in accordance with the design outlined in FIG. 5. This diagram shows an example of how the current in a load 314 can be increased using the flux pump technologies described herein. Note that over time, the current in the load 314 is positive, and increases on a cycle-by-cycle basis, where it is maintained at a constant level of over 7.5 A, before decaying when the motor driving the rotor 302 is stopped (at approximately 650 seconds).

It should be appreciated that the results derived in FIG. 6 are from experiments conducted by the inventors, and accordingly while they prove the principles of the technology, they may not be representative of the limits or overall performance of different forms of the technology.

### 6.3. Rotor Configuration

While the concept of the present technology may be provided using a rotor constructed of any material, there are advantages of providing a rotor 320 comprising a material with a high magnetic permeability, such as any suitable ferromagnetic material. For example, it may be advantageous to construct the support members 311 (arms or plate) of the rotor of a material with a high magnetic permeability to provide the magnetic path between the rotor and stator indicated by the arrows in FIGS. 4A, 4B and 5.

It should be appreciated that not all components of the rotor need to be constructed of a material having a high magnetic permeability, for example the shaft 316, may be constructed of any suitable material, including those without a high magnetic permeability.

The use of a material with a high magnetic permeability can improve the magnetic field coupling between the magnetic field generator(s) and the induction coil 310 and switch 312 as described herein. For example, any one or more parts of the rotor 302 may be constructed of iron or steel or any other ferromagnetic material to provide an electromagnetically conductive path. Use of steel may be particularly advantageous in some applications of the technology due to its low-cost and easy commercial availability.

In some examples of the technology, the rotor comprises a shaft 316 which may be connected to a drive means (not shown) such as a motor to enable rotation of the rotor 302.

It should be appreciated that to maintain a superconducting material 308 in a superconducting state, low temperatures are required. Accordingly, in one example of the technology, the rotor 302 may be positioned externally to a cryostat which contains the stator. In this way, heat generation for example, due to rotational friction generated by the moving rotor 302, does not cause the temperature of the superconducting material 308 to increase, or the cryogenic cooling requirements to increase.

### 6.3.1. Magnetic Field Generator(s)

As previously discussed in relation to FIGS. 3 to 5, the magnetic field generators 306 are positioned on the rotor 302 so that the respective magnetic fields are applied to the induction coil 310 and switch 312 as the magnetic field generators 306 rotate around past these components. For example, the magnetic field generators may be positioned on the side of the rotor 302 nearest the stator 304. However, this should not be seen as limiting, for example in a low-profile version of the technology, the magnetic field generators 306 may be provided on the distal end of an arm of the rotor 302, or in examples where a circular rotor is used, the magnetic field generators 306 may be provided on an outer perimeter of the rotor 302.

In certain forms, the magnetic field generators 360 are positioned at a radial distance from the rotation axis 317, so that each magnetic field generator travels through an arcuate or circular path in use. It can be advantageous for each of the one or more magnetic field generators to follow substantially the same arcuate or circular path in use. For example, each of the one or more magnetic field generators may have substantially the same radial distance from the rotation axis 317.

The magnetic field generator(s) 306 may comprise any suitable component or system capable of providing or generating a magnetic field. In one example of the technology, each magnetic field generator 306 is a permanent magnet such as a permanent magnet constructed from one or more of, samarium cobalt (SmCo), Alnico or neodymium iron boron (NdFeB) or any other suitable magnetic material. The use of a permanent magnet may advantageously allow for a simpler construction, and reduced heat generation in comparison with active magnetic field generating systems, such as transformer-based flux pumps or electromagnets.

In one alternative example of the technology, one or more of the magnetic field generators 306 may comprise an electromagnet. For example, where one or more electromagnets are used, the electromagnets may be configured to generate their respective magnetic fields continuously. In an alternative example one or more of the electromagnets may be configured to generate their magnetic field periodically. For example, the position of the rotor 302 may be determined in use, and the electromagnets activated at an appropriate time based on the position of the rotor 302. For example, the electromagnets may be activated when they are close to or approaching the induction coil 310 or switch 312. Determining the position of the rotor 302 may be performed using any method known to those skilled in the art including, using a rotary encoder.

For example, in one form of the technology it may be advantageous to control the activation of the one or more of the magnetic field generators 306 to adjust the relative timing between the current being induced in the induction coil 310, and the timing of the switch 312 transitioning from the low-resistance state to the higher-resistance state. For example where electromagnetic or transformer-based magnetic field generators are used, the magnetic field may be activated or deactivated by any suitable control circuit which may be familiar to those skilled in the art. Doing so may be beneficial to optimise the current transfer into the load 314. For example, where electromagnets are used, the position of the rotor, and therefore electromagnets relative to the stator may be determined using any suitable method, including those described above. Accordingly, the timing of the activation of the electromagnets may be adjusted, either by advancing the activation time, or by delaying the activation time. As the resulting current induced into the load can be measured, these timing adjustments may be correlated to the current induced into the load in order to determine optimal electromagnet activation timing.

In examples of the technology where permanent magnets are used as the magnetic field generators 306, the flux pump may advantageously be able to operate more efficiently, as there is less heat generated by the windings which would otherwise be generated by electromagnetic magnetic field generators 306.

Furthermore, in examples described herein, the present technology may be implemented using any number of magnetic field generators 306. For example, a single magnetic field generator may be used to generate a magnetic flux to flow through the stator 304, such that it induces current flow in the induction coil 310, and activation of the switch 312 simultaneously, or in a timed relationship to each other.

### 6.3.2. Rotor Constructions

The rotor 302 may have any suitable construction as should be known to those skilled in the art. For example, in the configuration shown in FIG. 5 the rotor 306 is a substantially flat cylindrical or circular plate. In other examples, the rotor may comprise one or more arms extending radially outwardly of the rotation axis 317 to provide the supports 311 described herein. Accordingly, the rotor 302 can have any suitable shape or configuration capable of causing rotation of the magnetic field generators.

In some examples of the technology, a single magnetic loop may be provided such as the configuration in which portions of the rotor and stator together form a magnetic loop, as discussed in relation to FIGS. 4A, and 4B, or alternatively two or more magnetic loops may be provided by portions of the rotor and stator such as shown in FIG. 5. One advantage of configuring the rotor and stator to provide two magnetic loops is that the time, or phase relationship between the changing magnetic field being induced in the first loop relative to the changing magnetic field induced in the second loop may be different.

### 6.4. Cryogenic Cooling

In order to maintain a superconducting material 308 in a superconducting state, low temperature, or cryogenic environments are often required. Accordingly, one advantage of certain forms of the present technology is that the rotor 302 may be provided in a non-contact arrangement with the stator 304. Accordingly, the stator 304 may be positioned within a cryostat 702, and the heat generating components of the rotor 302 positioned outside of the cryostat 702.

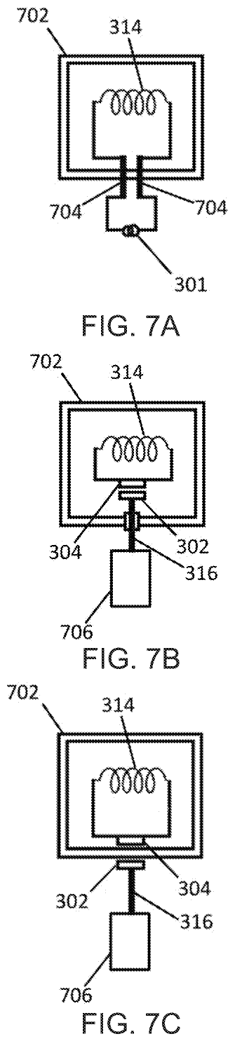

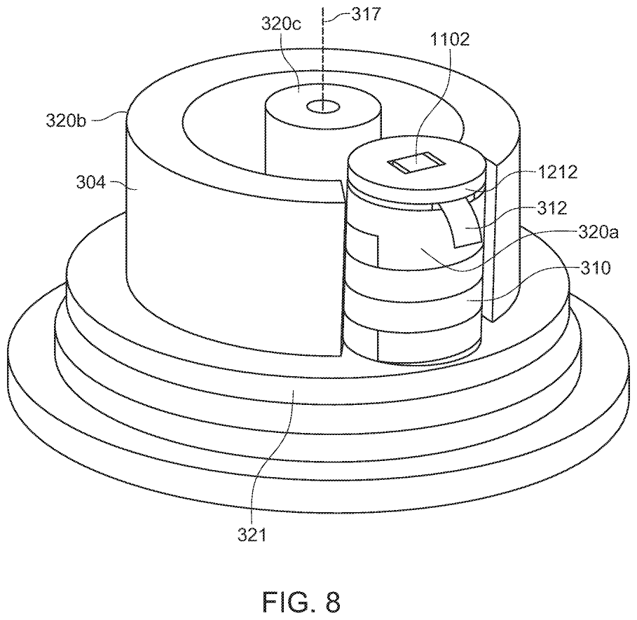

FIG. 7A shows a conventional generation circuit, wherein a power supply 301 or other current generating source is located externally to a cryostat 702, and is electrically connected to a load 314, or superconducting loop housed within the cryostat 702. For example, in FIG. 7A electrical leads 704 may be configured to penetrate the cryostat 702 to transfer the current flow to the load 314. One downside to the use of electrical leads 704 is that they provide a heat conducting path out of the cryostat 702 which can increase the overall cooling requirements of the system.

FIG. 7B shows an alternative configuration, for example in accordance with certain forms of the present technology, in which the rotor 302, stator 304, and load 314 are positioned within the chamber, and the drive means 706 such as an electric motor may be positioned externally to the cryostat 702, to reduce the overall cooling requirements of the system. In this example, the shaft 316 still penetrates the wall of the cryostat, however unlike in the example of FIG. 7A it may be possible to form shaft 316 from materials having a relatively low thermal conduction, or otherwise have insulating properties, such as carbon fibre.

FIG. 7C shows a yet further configuration, for example in accordance with certain forms of the present technology, in which the rotor 302 and drive means 706 are positioned externally to the cryostat 702, while the stator 304 and load 314 are positioned within the cryostat 702. One benefit of this arrangement is that the cryostat 702 can be completely sealed off from the heat/flux generating components, thereby potentially reducing the cooling requirements of the system. However, one potential downside to this approach is a reduction in the magnetic field coupling, or otherwise an increased flux gap between the rotor 302 and stator 304, which is described in more detail herein.

In some examples of the technology, the cryostat 702 comprises a cryostat refrigeration system as should be familiar to those skilled in the art. For example, the cryostat refrigeration system may comprise a liquid cryogen operable to cool by latent heat of evaporation, and/or a thermo-mechanical refrigerator. For example, liquid nitrogen may be used.

The cooling chamber 702 may comprise any suitable insulation, including any one or more of a vacuum, multi-layer insulation and/or cooled thermal shield. Where the chamber 702 wall is located between the rotor 302 and stator 304 it may be advantageous to use a material with a low electrical conductivity, such as a glass fibre composite, stainless steel and/or a thin/slitted multilayer foil.

### 6.5. Stator Configuration

In broad terms, the purpose of the stator is to position the induction coil 310, and switch 312 such that the passing magnetic field generators 306 on the rotor 302 provide a changing magnetic field which can induce a current flow in the induction coil 310, and transition the switch 312 from the low-resistance state to a higher resistance state.

In certain forms, the stator 304 may be constructed of any suitable ferromagnetic material, or any material with a suitably high magnetic permeability to more efficiently couple the magnetic field between the rotor 302 and stator 304. For example, the stator 304 may be constructed of iron or steel or any other ferromagnetic material to direct the magnetic field from the magnetic field generators through the loop of the induction coil 310, and switch 312. Use of steel may be particularly advantageous in some applications of the technology due to its low-cost and easy commercial availability. The use of a ferromagnetic stator may be advantageous in inducing sufficient current in the one or more lengths of superconducting material 308, which exceeds the field-suppressed critical current of the switch 312, and applying a strong enough field to the switch 312 in order to reduce it's critical current below the induced current, or otherwise transition the switch 312 from a low-resistance to a higher-resistance state as described herein.

In some examples of the stator described herein, the stator comprises one or more arms 320A, 320B, 320C which are configured to extend upwardly from a stator base 321 towards the rotor 304. Accordingly the use of stator arms 320 may advantageously allow for a smaller airgap between the rotor 302 and stator 304, improving the efficiency of the transfer of the magnetic field from the magnetic field generators to the stator 304.

The stator 304 may further comprise features which allow the relative positioning of the induction coil 310 to the switch 312 to be adjusted as described herein. For example, the switch 312 may be provided on a switch holder 1212 as described herein which allows for easy adjustment of the switch positioning on the stator.

### 6.5.1. Superconducting Material

In the examples described herein the one or more lengths of superconducting material 308 may include a high-temperature superconductor such as a rare-earth Barium Copper Oxide (ReBCO) tape, (including for example, those manufactured by SuNam™). However, this should not be seen as limiting on the technology, and any suitable superconducting material 308 may be used as described herein.

The foregoing discussion provides examples of how the one or more lengths of superconducting material 308 may be structured and/or arranged to provide the induction coil 310, switch 312 and load 314. For experimental purposes the components of the induction coil 310, load 314 and/or switch 312 have been electrically connected using normally conducting joins such as solder joints. However, this should not be seen as limiting on the technology. For example, in some examples of the technology, superconducting material 308 may comprise a continuous tape, or other suitable material which is arranged to provide any one or more of the induction coil 310, load 314, and/or switch 312.

More specifically, in some examples of the technology, the induction coil 310 may be provided by looping a coil of the superconducting material 308 around one of the arms 320A, 320B, of the stator 304. Similarly, depending on the switching configuration selected (more on this below), the switch 312 may be formed by positioning a portion of the one or more lengths of superconducting material 308 tape in a location in which the magnetic field applied to the superconducting material 308 has a component which is perpendicular to a surface of the length of superconducting material 308 which provides the switch 312.

Where components of the technology are provided in parallel, these may be also be provided from a continuous superconducting material 308 such as a tape, for example by splitting the tape along its longitudinal axis (or lengthways) in order to provide two parallel paths of superconducting material 308 which are integrally connected, i.e. have a superconducting connection between each parallel path.

### 6.5.2. Induction Coil

The reader should be familiar with the concept of induction coils in accordance with Faraday's law. However, unlike a traditional transformer, the present technology uses magnetic field generators 306 such as permanent or electromagnets to generate the electromagnetic field. Accordingly, the technology is able to address a number of the issues with transformer-based flux pumps, such as heat generation due to the currents in the primary of the transformer.

It can be advantageous to maximise or otherwise increase the current flow in the induction coil 310 to induce as much current flow in the flux pump as possible. A higher current flow can result in more current being transferred to the load 314 or output terminals 315, as well as a higher resistance of the switch in the higher-resistance state, since the resistance of the switch is dependent on the field suppressed critical current, and the current flow through the switch as shown in FIG. 2.

In certain forms of the technology, the induction coil 310 may comprise any number of turns of a superconducting material such as a tape, including partial (i.e. non-integer numbers of) turns. For example, the results illustrated in FIG. 6 were provided with one full turn or less of a 12 mm wide superconducting tape 308. However, any number of turns may be used, and as noted above, it can be advantageous to maximise the number of turns provided in the space available. By way of example, in the forms of the technology described herein, and which provide the experimental results of FIG. 6 the stator arm 320 had a height of approximately 50 mm to ensure there was sufficient room on the arm 320 to support the tape.

The foregoing however should not be seen as limiting on the technology however, for example more than two windings may be used. In some examples of the technology, it may be advantageous to provide the induction coil 310 from a superconducting wire rather than using a tape, in order to provide a greater number of turns in the available area on the stator arm 320.

It should further be appreciated that where superconducting materials are used, these materials can have bend radius limitations, and therefore in preferred examples of the technology, the diameter of the stator arms 320 (around which the length of superconducting material may be wound) may be configured to ensure that the bend radius limitations are not exceeded. For example, the stator arm 320 may have a substantially cylindrical shape with a diameter of greater than or equal to the minimum bend radius of the one or more lengths of superconducting material 308. In some examples, the superconducting material may have a minimum bend radius of 5 mm or more, and therefore the diameter of the stator arm 320 should be dimensioned accordingly, i.e. greater than or equal to 5 mm. In the examples shown, the stator arm 320 has a diameter of approximately 50 mm.

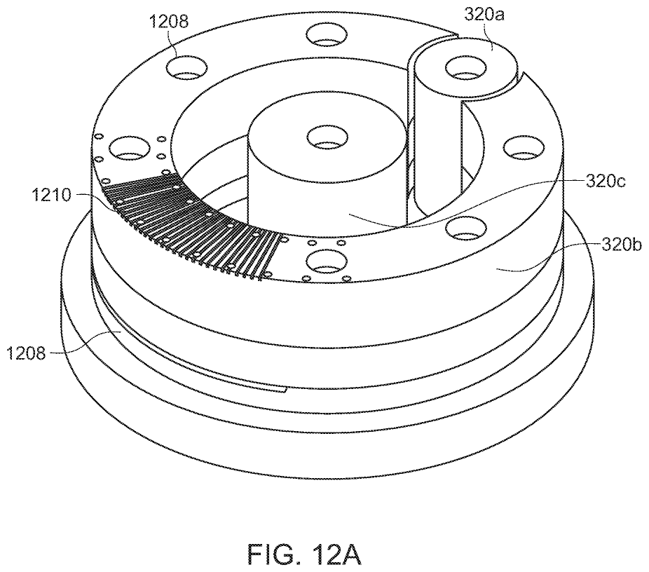

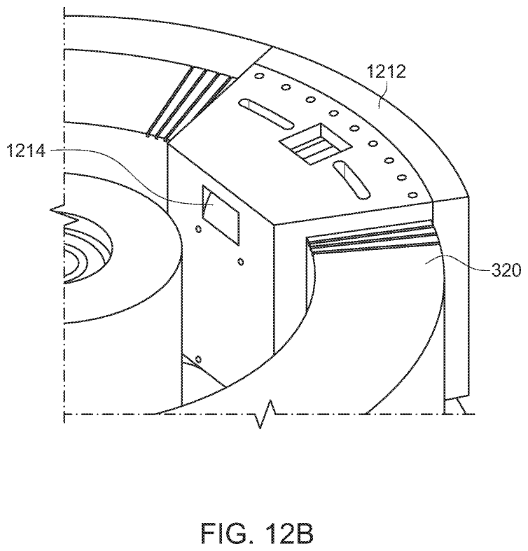

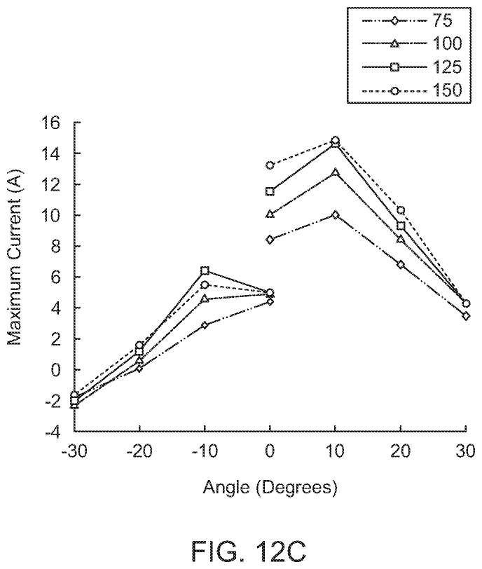

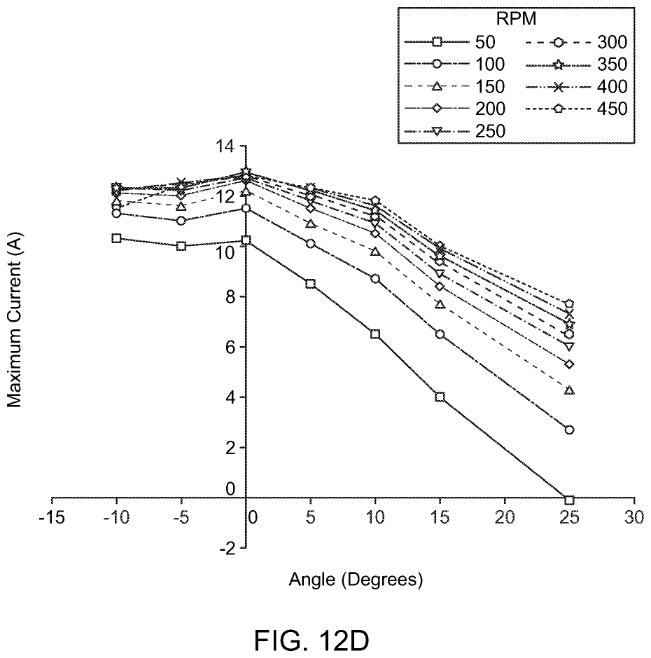

One example of a stator 304 is shown in FIG. 8. In this example, the stator 304 comprises a stator base 312, from which a plurality of stator arms 320 extend substantially perpendicularly upwards away from the stator base 321, towards a rotor 302 (not shown in FIG. 8). For example, in FIG. 8, a first stator arm 320a, has a cylindrical annulus construction, while the second stator arm 320b is provided as an annular wall. The second stator arm 320b may form a gap along a segment of its circumference, and the first stator arm 320a may be positioned in the gap, as illustrated. A third central stator arm 320c provides a return path for the magnetic field as shown in FIG. 5. A similar arrangement is also shown in FIG. 12A.

In examples of the technology, where the second stator arm 320b has an annular construction as in FIG. 8, it may be advantageous for the gap between the first stator arm 320a and the second stator arm 320b to be less than a width of the magnetic field generator 306. This arrangement may advantageously reduce the effects of cogging torque on the rotor 302. Cogging torque may occur when the magnetic field doesn't transition smoothly from one flux path to the next. This may cause the rotor 302 to accelerate and decelerate as it passes the iron tooth, and its motion may become non-linear.

The first stator arm 320a may be provided with a coil of one or more lengths of superconducting material 308 structured in one or more loops around the arm 320, to provide an induction coil 310. The radius of the cylinder may be selected such that it is greater than or equal to the minimum bend radius of the one or more lengths of superconducting material 308, so as to prevent damage to the one or more lengths of superconducting material 308 as the induction coil 310 is wound around the arm 320.

The stator arm 320a may further support a switch 312 in a similar construction as shown in FIG. 4A. The switch 312 may be a component which is configured to transition between a low-resistance state and a higher-resistance state in the presence of a magnetic field as described herein. In the illustrated example, the switch 312 may be referred to as a “J_{c}(B) switch” as will be described in more detail herein. However, this should not be seen as limiting on the technology, and suitable superconducting switch 312 may be used in accordance with the present technology.

The centre of the stator 304 is preferably aligned with the rotation axis 317 of the rotor, such that the arcuate path of the magnetic field generators 306 travels close to the first and second stator arms 320a, 320b. In other words, it can be advantageous for the switch 312, and induction coil 310 to have substantially the same radial distance from the rotation axis 317 as the distance of the one or more magnetic field generators from the rotation axis 317.

### 6.5.3. Switch

The present technology may be configured for use with any suitable switch 312 as should be familiar to those skilled in the art. In preferred examples of the technology, the switch may be a type of switch that may be referred to as a “J_{c}(B) switch”. For the purposes of this specification, a J_{c}(B) switch operates by changing the critical current of one or more lengths of superconducting material 308 by subjecting it to a magnetic field, for example a magnetic field having a direction (or a component having a direction) perpendicular to the surface of the length of superconducting material). The magnetic field acts to suppress the critical current in the length of superconducting material, which, when the length of superconducting material carries an appropriate current, may act to transition it to a higher-resistance state, hence acting as a switch. As explained earlier, the one or more lengths of superconducting material 308 may remain superconducting in the higher-resistance state.

In one form of the technology the switch 312 comprises one or more lengths of superconducting material 308 positioned such that the magnetic field generated by the magnetic field generator 306 is applied to the superconducting material such that at least a component of the magnetic field is perpendicular to a surface of the one or more lengths of superconducting material. For example, the one or more lengths of superconducting material may be positioned on the end of a stator arm 320, between the stator and rotor, such that as the magnetic field generator passes the switch, the magnetic field from the magnetic field generator is applied to the one or more lengths of superconducting material 308 such that at least a component of the magnetic field is perpendicular to a surface of the superconducting material. In some forms the magnetic field may be substantially perpendicular to a surface of the superconducting material 308.

In one form of the technology, the switch 312 may be positioned on the stator at a distance from the rotational axis 317 of the rotor which is substantially equivalent to the distance of the magnetic field generator 306 from the rotational axis 317. In some examples, the switch 312 may be positioned between an arm 320 of the stator 304 and a field spreader 1102 as described herein. However, this should not be seen as limiting on the invention, as the magnetic field generated by the magnetic field generator(s) can be configured to be applied to the one or more lengths of superconducting material 308 such that at least a component of the magnetic field is perpendicular to a surface of the superconducting material. For example, with reference to FIG. 4A the switch may be provided on the second arm 320B of the stator, between the rotor 302 and stator 304.

In other forms of the technology, the stator may have a multiple part construction. For example, the stator may comprise a first stator component and a second stator component, wherein the switch is positioned between the first stator component and the second stator component.

J_{c}(B) switches may be used due to the low-circuit complexity, high off-state resistance, and fast response times in certain forms of the technology. However, this should not be seen as limiting on the technology, and other potential switch mechanisms which may be used in combination with features of the present technology include:
Heat switches, i.e., switch mechanisms which induce a temperature rise in the one or more lengths of superconducting material 308 to change the Ej behaviour (electric field to current density) and transition the switch 312 from a low resistance state to a higher resistance state.
Cryogenic MOSFETs.
Self-rectification, which describes a passive switching process due to a switch portion of the one or more lengths of superconducting material 308 having a lower critical current than the rest of the circuit. In use a current pulse is provided to the one or more lengths of superconducting material 308 which exceeds the critical current of the switch portion, transitioning the switch portion from a low resistance state to a higher resistance state.
AC-field rectifiers which use an electromagnet to produce an AC field oriented in a normal direction to a superconducting tape, thereby increasing its resistance.
Screening current loops, such as those described in PCT publication No. WO/2021/080443, the contents of which are herein incorporated by reference in their entirety.

While these other switching technologies may be used, it should be appreciated that they may have a number of limitations in comparison with the J_{c}(B) switch. For example, heat switches typically cannot be operated at high frequencies, and therefore may be less suitable for use in regulating applications. There is also a need for a heat source, and control circuitry, often resulting in increased cooling requirements. Similarly, the conducting (low resistance state) resistance of cryogen MOSFETs is non-zero which can add to the heating of the system. Self-rectification circuits have a simple overall topology, but they are less flexible, and cannot allow for full-wave rectification of the current.

While AC-field rectifiers may be similarly suitable for use with the present technology, we note that certain AC-field rectifiers rely on dynamic resistance to transition the switch 312 to the higher resistance state. In contrast, J_{c}(B) switches operate on the principle that the critical current of a one or more lengths of superconducting material 308 changes when it is subjected to a perpendicular magnetic field i.e. the E-J behaviour of the switch 312 is modified.

There is also some evidence which suggests that the off-state resistance of J ((B) switches can be higher than the dynamic resistance caused by AC-field rectifiers, which may result in more efficient regulation.

Forms of the technology make use of different mechanisms that may be used to effect switching of an electrical switch 312 formed from (including comprising) a superconducting material. The individual mechanisms will now be described, and then examples of how certain forms of the technology utilise the mechanisms in combination will be described.

### 6.5.3.1. Effect of Magnetic Field on Critical Current of Superconducting Materials

The critical current in a superconducting material 308 is dependent on the external magnetic field applied to the superconducting material 308. More particularly, the critical current decreases as a higher external magnetic field is applied to the superconducting material 308, up to the value of the critical field, above which the superconducting material 308 is no longer in the superconducting (low resistance) state. This relationship is shown in FIG. 2, which is an illustration of graphs of electric field against current for a superconducting material when three external magnetic fields of different magnitude are applied. The highest magnitude of external magnetic field, Bₐₚₚ₁, results in the lowest critical current, la.

Forms of the technology relate to electrical switches that utilise the principle that the critical current of a superconducting material decreases as a higher external magnetic field is applied to the material. By selectively applying a magnetic field to a superconducting material, for example a magnetic field that is substantially constant over a period of time (i.e. a DC field), the critical current can be raised or lowered relative to the transport current in order to switch the superconducting material between a low-resistance state and a higher-resistance state. In certain forms, a combination of switching mechanisms may be used. That is, in some forms a high-temperature superconductor (HTS) may need to have an impracticably high field applied to it for the field itself to switch the superconducting material 308 into the higher-resistance state which is non-superconducting, but fields of a practical magnitude may be applied to reduce the critical current sufficiently for another mechanism to effect switching.

### 6.5.3.2. Effect of Time-Varying Magnetic Field on Superconducting Materials-Dynamic Resistance & Heating

Certain forms of the technology may utilise the phenomenon of dynamic resistance. This occurs when a superconducting material 308 is exposed to a time-varying magnetic field while carrying a DC transport current. This creates a DC electrical resistance in the superconducting material 308, which may be sufficiently large that the superconducting material 308 switches into a higher-resistance state.

The DC electrical resistance in the superconducting material 308 caused by this phenomenon may additionally lead to energy loss through heating of the superconducting material 308. When a time-varying magnetic field is applied to a superconducting material 308 there may also be heat loss due to magnetisation. The loss due to dynamic resistance may occur in the region of the transport current, for example a central region of the length of superconducting material, while the magnetisation loss may occur in the edge regions of the superconducting material. The amount of heating may depend on the frequency and amplitude of the applied time-varying magnetic field.

The time-varying magnetic field that causes the dynamic resistance phenomenon may be an alternating magnetic field, for example a magnetic field varying sinusoidally.

In the case of a superconducting material having a length significantly larger than its width or depth (e.g. a wire or tape), dynamic resistance is mainly caused by the component of the time-varying magnetic field that is applied to the superconducting material that is perpendicular to the direction along the length of the material.

### 6.5.3.3. Heating of Superconducting Materials

As explained above, the critical current of a superconducting material is a function of both the type of superconducting material used, and the physical arrangement of the superconducting material. The critical current is also dependent on the temperature of the superconducting material. As the temperature of the superconducting material increases, the critical current decreases. This relationship continues up to the critical temperature, above which the superconducting material is no longer superconducting.

Forms of the technology relate to electrical switches that utilise the principle that the critical current of a superconducting material decreases as the temperature of the superconducting material increase. By selectively heating a superconducting material, the critical current can be raised or lowered relative to the transport current in order to switch the superconducting material between a low-resistance state and a higher-resistance state.

Different forms of the technology may use different mechanisms to heat the superconducting material in the electrical switch 312 and forms of the technology may not be limited to the mechanism used to achieve the heating. Nevertheless, two examples of mechanisms for heating a superconducting material are provided in exemplary forms of the technology. These two mechanisms are now briefly explained.

Firstly, a heating element may be positioned in thermal contact with the superconducting material. The heating element may be, for example, a resistive heating element that converts electrical energy into heat energy through the process of Joule heating as an electrical current flowing through a conductor encounters electrical resistance. The heating element may be positioned in physical contact with the superconducting material to primarily heat the material through conduction, or spaced from the superconducting material to primarily heat the material through convection and/or radiation.

Secondly, forms of the technology may utilise the heating effect caused by applying a time-varying magnetic field (for example, an alternating magnetic field, which may be referred to as an AC field) to a length of superconducting material resulting from the phenomenon of dynamic resistance and magnetisation, as explained above.

### 6.5.3.4. Screening Current

Applying a time-varying magnetic field to a loop of superconducting material causes a screening current to flow around the loop which, in combination with a transport current carried by the loop, may exceed the critical current of the superconducting material. Consequently, by selectively applying a time-varying magnetic field to a loop of superconducting material, the loop may be transitioned between a low-resistance state and a higher-resistance state.

Forms of electrical switches utilising this switching mechanism will now be described. It should be appreciated that, where features are described in the following in relation to exemplary forms of electrical switch 312 utilising this mechanism alone, those features may also be used in any of the forms of electrical switches utilising combinations of switching mechanisms later in this specification. Further details of this switching mechanism are provided in PCT Application No. PCT/NZ2020/050132, the contents of which are herein incorporated by reference.

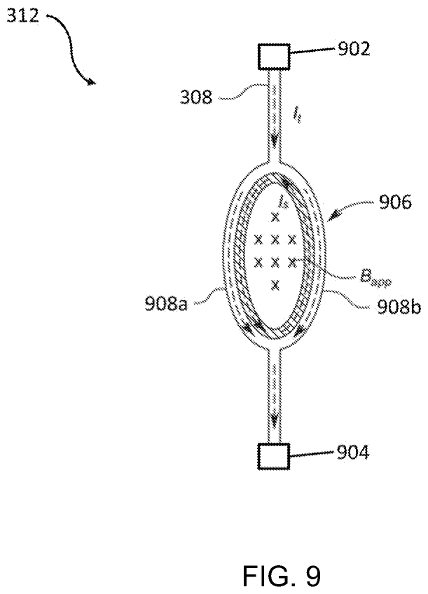

FIG. 9 is a schematic view of a switch 312 operating based on the principle of induced screening current. The switch 312 includes one or more lengths of superconducting material 308 which is connected between a first terminal 902 and a second terminal 904. The use of terminals in the present example should not be seen as limiting on the technology, and the switch may be integral with the other components of the superconducting material 308 described here such as the load 314 and induction coil 310.

In use a transport current Iₜ flows between the first terminal 902 and second terminal 904, for example as the magnetic flux is induced in the stator 304 due to the magnetic field generator(s). It should be appreciated that the transport current Iₜ may be time-varying, and provided at a phase or time offset relative to the current induced in the induction coil 310.

The transport current Iₜ is shown as flowing from the first (positive) terminal 902 to the second (negative) terminal 904 as would be expected for conventionally defined direct current (DC) voltages. The superconducting material 308 between the two terminals 902, 904 is formed in a loop 906 which comprises two electrically parallel superconducting branches 908a, 908b.

The branches 908a, 908b may be formed using any method which provides a substantially zero resistance joint, such as by splitting a superconducting tape into two parallel branches. Alternatively, a non-zero resistance joint may be used such as by soldering.

In use a transport current is applied between the first terminal 902 and second terminal 904, a time-varying magnetic field Bₐₚₚ(t) is then selectively applied to, or within, the loop 906 in a direction which is normal to (or has a component which is normal to) the plane of the loop 906, i.e. parallel to an axis of the loop 906 where the axis is normal to the plane of the loop 906. For example, the time-varying magnetic field may be applied to the loop by passing the stator arm 320 through the loop.

This time-varying magnetic field Bₐₚₚ(t) causes a screening current (Iₛ) to flow around between the branches 908a, 908b of the loop 906 in order to oppose the flux change in the loop 906. This screening current Iₛ adds to the transport current flowing around the loop 906 and as a result the total current flowing increases. This increase in current may result in a marginal increase in the resistance of the superconducting material (for example when the current is less than the critical current I_{c}) or a substantial increase in the resistance of the superconducting material (for example when the current I_{c} is near to, greater than, or equal to the critical current for the superconducting material 308).

### 6.5.3.5. Combinations of Switching Mechanisms

It should be appreciated that the switch 312 may be constructed using any combination of the aforementioned switching mechanisms. For example, the switch 312 may be constructed using a combination of:
Self-rectification together with a Jc(B) switch. In other words, the section of the superconducting material which is exposed to the perpendicular magnetic field may be configured to have a lower critical current than the rest of the superconducting material.
Self-rectification together with a screening current loop. In other words, the section of the superconducting material used in the loop 906 may be configured to have a lower critical current than the rest of the superconducting material.
A screening current loop together with an AC-field rectifier. In other words, a loop may be formed in the superconducting material 308 to provide a screening current loop switch 312. In use a time-varying magnetic field may be passed through loop, and through part of the superconducting material.

### 6.5.4. Load

In some examples of the technology described herein a load 314 is connected in parallel with the switch 312. This configuration should not be seen as limiting on the technology, as in some applications it can be desirable to use a flux pump to increase the current flow in a load, before disconnecting the load from the flux pump for use elsewhere. In other words, the present technology may comprise two or more output terminals configured to connect to a load in use, the two or more output terminals being electrically connected in parallel with the switch.

The load 314 may be a load coil, or any circuit which in use receives the current from the flux pump described herein. In some examples, the load 314 consists of a loop of superconductive material as should be familiar to those skilled in the art. In other examples, the load 314 is part of a superconducting circuit. Accordingly, the flux-pump configurations described herein may be used to both increase the current flow in a one or more lengths of superconducting material 308 on a cycle-by-cycle basis, as well as maintaining the current flow in the one or more lengths of superconducting material 308 during use.

### 6.6. Improved Flux Pump Arrangements

While the foregoing discussion may provide a functional flux pump, the inventors have identified further improvements to the technology. These include any one or more of:
Adding shunt resistance between the induction coil 310 and the load 314 and switch 312;
Using a field spreader 1102 to improve the flux penetration of the J_{c}(B) switch 312;
Tuning the flux gap, to improve electromagnetic field coupling between the rotor 302 and stator 304; and
Adjusting the phase angle/timing relationship between the induced current in the induction coil 310 and the activation of the switch 312.

Each of the foregoing will now be discussed in greater detail.

### 6.6.1. Shunt Resistance

As previously discussed, it is currently not possible or otherwise not commercially viable to create superconducting joints in high-temperature superconducting materials. Accordingly, while the present invention may be implemented using a single continuous length of superconducting material 308, appropriately configured to provide the induction coil 310, switch 312 and load 314, in some examples of the technology it may be beneficial to include one or more joints, such as normally conducting joints as should be familiar to those skilled in the art.

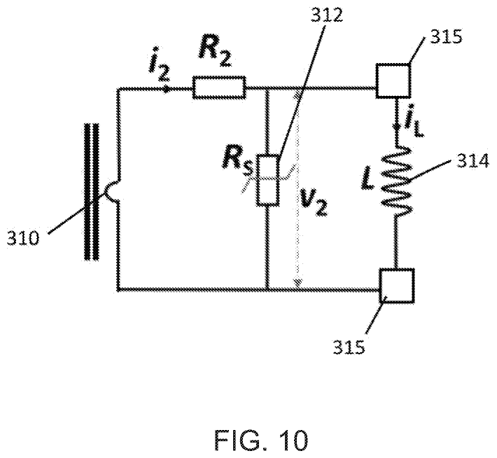

FIG. 10 shows a modified version of the FIG. 3 schematic in which a shunt resistance R₂ has been introduced between the induction coil 310, and parallel switch 312 and load 314. This shunt resistance, may be representative of resistance introduced by, for example, a normally conducting joint, such as a solder joint as should be familiar to those skilled in the art. It should be appreciated that by overlapping one or more lengths of normally conducting material, (otherwise known as a lap joint) the relative resistance of the normally conducting material may be lower, than by using joining methods such as end-to-end or but joints. In some examples of the technology, normally conducting materials such as copper may be used.

In other words, in certain forms of the technology the flux pump may comprise a shunt resistance connected electrically in series between the induction coil 310 and switch 312. For example, the shunt resistance may be provided by a normally conducting joint.

It should be appreciated that the current into the load 314 is proportional to the voltage across the load V₂, accordingly by increasing the voltage V₂ it is expected that the current in the superconducting material 308 should increase. Conventional wisdom therefore is to use a shunt resistance R₂ which is as small as possible to reduce the effects of R₂ on the resulting voltage divider between R₂ and the combined impedance of the load 314 in parallel with the switch 312 Rs. However, the inventors have found that increasing the shunt resistance value R₂ can result in higher load currents in the load 314.

Assuming that the current i₂ is at steady state, the voltage V₂ is defined by:

$${V}_{2} = - {i}_{2} {R}_{2}$$

Accordingly, increasing the shunt resistance value R₂ may result in an increased voltage V₂. The higher the voltage V₂, the faster the current may be transferred to the load 314. Further assuming that I_{L} is the maximum load current:

$${V}_{2} = {i}_{L} {R}_{L}$$

Further combining the above equations gives:

$${i}_{L} {R}_{L} = - {i}_{2} {R}_{2}$$

Accordingly, the maximum load current it is determined by i₂ and the ratio of R₂ to R_{L}. If R₂ is small, the maximum load current will also be small. Accordingly, it can be advantageous to increase the resistance of the induction coil 310, and switch. A further advantage of introducing the shunt resistance R₂, is that it can allow for easy measurement of the current flowing within the circuit.

### 6.6.2. Field Spreader

Further improvements to the flux-pump design described herein may be provided by improving the flux penetration of the switch 312, to allow for larger resistance differences between the low-resistance and higher resistance states. In other words, by exposing the switch 312 to higher strength magnetic fields, it may be possible to get a larger reduction in the critical current of the superconducting material 308 as illustrated in FIG. 2.

Accordingly, one feature of the present technology is to provide a field spreader 1102 which is used to couple the magnetic field from the rotor 302 and provide a homogenous magnetic field on at least a portion of the switch, such as the one or more lengths of superconducting material of the switch 312. Use of the term field spreader throughout the present specification should not be seen as limiting and should be understood to mean any component which is configured to direct the magnetic field through a component of the super conductor, and in particular through the switch, for example by providing a homogenous field through the switch. The term “spreader” should be interpreted in the context of directing the magnetic field or otherwise coupling or evenly distributing the magnetic field. In some examples of the technology the field spreader may concentrate the magnetic field in order to increase the coupling of the magnetic field to the switch.

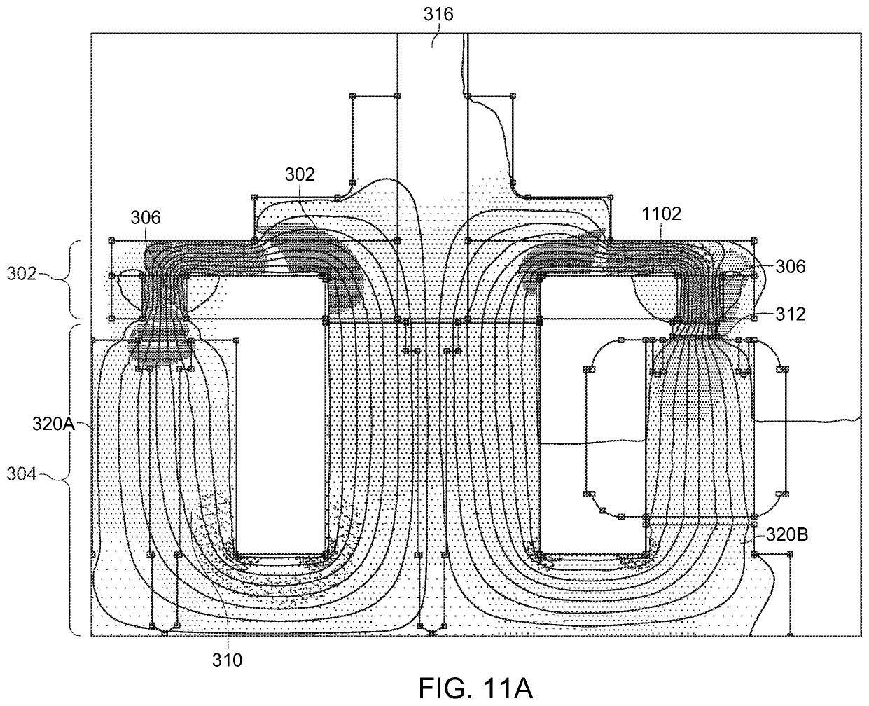

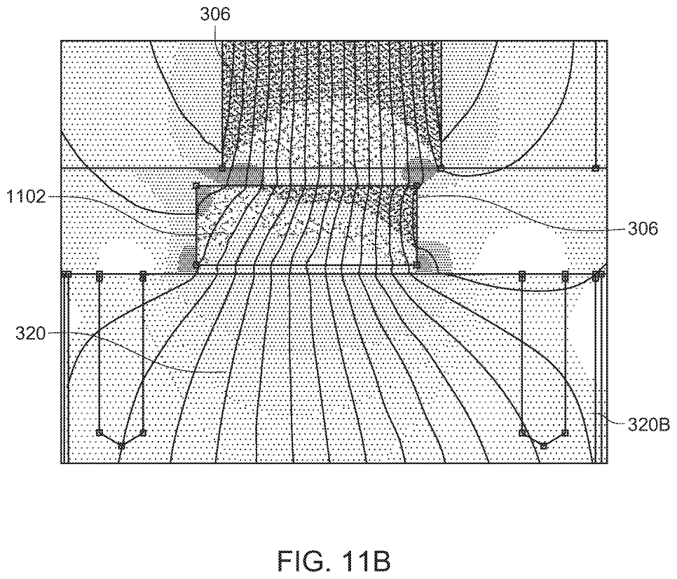

FIGS. 11A and 11B show an example of how the magnetic field intensity may be distributed within the rotor 302 and stator 304, in accordance with the flux-pump design of the form illustrated in FIG. 3. As shown, the stator 304 is provided with a field spreader 1102, configured to concentrate or otherwise direct the magnetic field from the rotor 302 through the switch 312. To achieve this the field spreader 1102 is preferably comprised of a material having a higher magnetic permeability than the environment surrounding the field spreader 1102, for example where the field spreader 1102 is in an air environment the field spreader 1102 should have a higher magnetic permeability than the air, for example iron may be used.

The field spreader 1102 may be positioned between the magnetic field generator 306, and the switch 312 on the stator 304, such that as the magnetic field generator moves past the field spreader 1102 it generates a homogenous magnetic field for the switch 312 portion of the superconducting material 308.

It may further be beneficial to ensure that the field spreader 1102 is positioned substantially centrally on the stator arm 320A so as to minimise the maximum distance measurable from an edge of the field spreader 1102 to an edge of the stator arm 320, see D1 and D2 in FIG. 11B.

It may also be advantageous for the field spreader 1102 to have substantially the same width as the magnetic field generator, so as to evenly couple the magnetic flux generated from the magnetic field generator through the field spreader 1102, through the switch 312 and into the stator arm 320.

### 6.6.3. Flux Gap

Those skilled in the art should appreciate that the separation between the magnetic field generator and the stator 304 should preferably be kept to a minimum in order to obtain maximum flux coupling between the rotor 302 and stator 304. This separation may be referred to as a flux gap. For example, the inventors found that a reduction in the flux gap from 6 mm to 1 mm resulted in an increase in induced current and voltage of 20%.

It should be appreciated that in examples of the technology wherein the stator 304 and rotor 302 are separated by a cryostat 702 as shown in FIG. 7C there is a trade-off between the flux gap, and the amount of insulation that can be positioned between the rotor 302 and stator 304.

### 6.6.4. Switching Phase Angle

In the foregoing examples the switch 312 has been positioned such that it is activated simultaneously with the induced current in the induction coil 310. For example, the induction coil 310 may be located on the same stator arm 320 as the switch 312, as shown in FIG. 8. In another example the induction coil 310 may be positioned directly opposite to the switch 312, (180 degrees opposite), in this example a plurality of magnetic field generators 306 are used, which are also positioned opposite to each other on the rotor 302. In this way as one of the magnetic field generators 306 passes over the induction coil 310, another of the magnetic field generators 306 passes over the switch 312, thereby synchronising the induced current with the rectification which results from increasing the switch 312 resistance.

With reference to FIG. 12A, the stator arms 320, described herein should be understood to include any component of the stator 304 which is configured to carry the magnetic field from the magnetic field generator on the rotor 302, and couple the magnetic field back to the rotor 302. For example, in FIG. 12A, this includes the central magnetic return path 320C, the steel/ferromagnetic tooth 320A which in use is attached to the induction coil 310, and the steel wall 320B.

The stator arm 320B may be configured to provide a wall allowing for continuous conduction of the magnetic flux generated by the magnetic field generators 306, including when the switch 312 and/or induction coil 310 are not in the direct presence of the magnetic field. This can advantageously reduce cogging torque as described herein.

Other features of the stator 304 in certain forms of the technology may include ring bolt holes 1208 which may advantageously allow for liquid coolant to flow into the stator 304, as well as for securing the components of the stator 304 together.

Also provided in the stator 304 may be an optional tape slot for the superconducting material of the switch 312 to pass through in use. In other words, the superconducting material may be looped around the stator arm 320 such that a portion of the tape sits between the stator arm 320, and the magnetic field generator as described herein. It should be appreciated that use of the tape slot is optional, and other switch 312 configurations, including bifilar configurations are described herein which do not require the tape slot.

In certain forms of the technology, such as those illustrated in FIGS. 12A, and 12B the flux pump may comprise a switch holder 1212 configured to adjust the position of the switch 312 relative to the induction coil 310 to be adjusted. For example the switch holder 1212 may be configured to engage with one or more of a plurality of angle markers 1210 correspond to potential switch 312 locations. For example the plurality of angle markers may be positioned to provide an offset of +/−1 degree each. This arrangement allows for the relative positioning and therefore phase relationship of the induced current in the induction coil 310, and the activation of the switch 312 to be adjusted. For example, FIG. 12B includes a switch holder 1212, the position of which is adjustable relative to the stator arm 320. The switch holder 1212 may be configured to slide along the annular stator arm 320. The stator arm 320 may be arc-shaped in other forms.

In certain forms of the technology, the switch holder 1212 comprises an opening, which in-use can receive a field spreader 1102 as described herein, and a slot 1214 which is configured to receive one or more lengths of superconducting material 308 in use. For example the switch holder 1212 may be configured such that the field spreader 1102 sits directly above the one or more lengths of superconducting material 308 and directs the magnetic field from the magnetic field generator into the one or more lengths of superconducting material 308 to generate the switching action described herein.

The switch holder is preferably constructed of a material having a low magnetic permeability and low electrical conductivity to reduce the generation of eddy currents. For example, the switch holder 1212 may be constructed of G10 (a high-pressure fiberglass laminate).

FIG. 12C shows an example of the maximum current generated by the design of FIGS. 12A and 12B with different switch 312 angle positions relative to the induction coil 310. Also tested and represented in the graph is the effects of different rotor 302 speeds in revolutions per minute. Note that there are two different zero values recorded on the graph, as the system was tested with the rotor 302 spinning in both a clockwise and counter-clockwise direction.

The results of the graph are summarised in the table below:

TABLE 1
Rotational Speed, Direction, and Phase
Offset Effects on Maximum Current

| Rotational Speed (RPM) | Angle (Degrees) | Maximum Current (A) |
|---|---|---|
| 75 (Anti-Clockwise) | −30 | −1.9 |
| | −20 | 0.1 |
| | −10 | 3.0 |
| | 0 | 4.4 |
| 75 (Clockwise) | 0 | 8.5 |
| | 10 | 10.0 |
| | 20 | 6.9 |
| | 30 | 3.5 |
| 100 (Anti-Clockwise) | −30 | −2.2 |
| | −20 | 0.6 |
| | −10 | 4.7 |
| | 0 | 5.0 |
| 100 (Clockwise) | 0 | 10.0 |
| | 10 | 12.9 |
| | 20 | 8.5 |
| | 30 | 4.3 |
| 125 (Anti-Clockwise) | −30 | −2.0 |
| | −20 | 1.2 |
| | −10 | 6.5 |
| | 0 | 5.0 |
| 125 (Clockwise) | 0 | 13.1 |
| | 10 | 14.7 |
| | 20 | 9.2 |
| | 30 | 4.2 |
| 150 (Anti-Clockwise) | −30 | −1.8 |
| | −20 | 1.8 |
| | −10 | 5.5 |
| | 0 | 5.0 |
| 150 (Clockwise) | 0 | 13.2 |
| | 10 | 14.9 |
| | 20 | 10.2 |
| | 30 | 4.2 |

The results indicate that there is some asymmetry within the test apparatus, which the inventors believe may be attributable to the low number of turns used in the induction coil 310, causing the area within the loop to be highly asymmetric.

Regardless of the above, it was found that peak load 314 currents were identified with a phase offset angle of 10 degrees, and it is believed that a phase offset of between 0 and 13 degrees may result in overall higher load 314 currents than having a zero-degree offset or a switch 312 and induction coil 310 which are diametrically opposed (180 degrees opposite) in a flux pump.

In other words, in certain forms of the technology, the flux pump may comprise a switch and an induction coil, wherein the switch is configured to be activated (switched from the low resistance state to the higher-resistance state) with a phase delay, or time delay relative to the current induced in the induction coil 310. More specifically it may be advantageous to position a switch 312 within a flux pump such that the switch 312 is activated within +/−13 degrees of the current being induced in the induction coil 310. In forms of the technology comprising two or more magnetic field generators 306, it may be advantageous to position the switch 312 between 167 degrees and 193 degrees relative to the induction coil 310. In other words, it may be advantageous to provide a phase delay of approximately +/−3.6% of the cycle of current being induced in the induction coil.

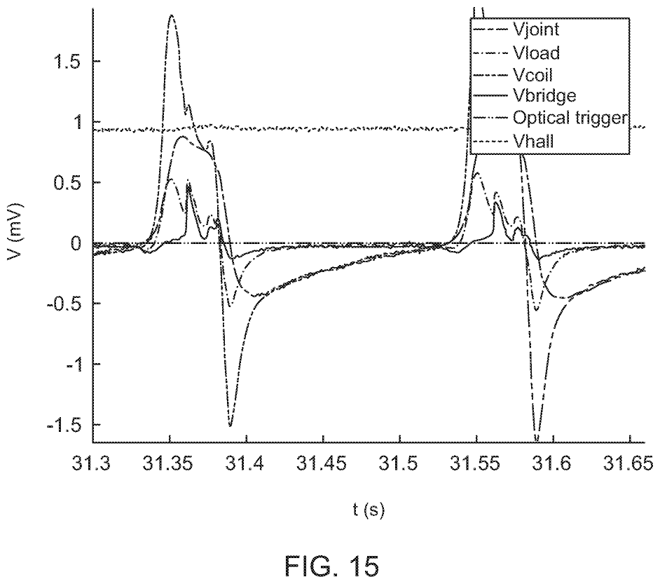

Use of a phase delay may advantageously allow for selective characteristics of the induced current in the induction coil to be rectified. For example, the phase delay between the induced current in the induction coil and the switch activation can be used to select specific characteristics of the induced current characteristics waveform which may be desirable, and therefore should be transferred to the load. For example, the current induced in the induction coil may be known to oscillate between positive and negative values as described herein in relation to FIG. 15 and, accordingly, by controlling the phase delay between the induced current in the induction coil and the switch activation, it is possible to select either the positive or negative portions of the induced current waveform for regulation. In other words, the flux pump devices of certain forms of the technology described herein may be configured to selectively regulate current flow in the positive and/or negative direction. Furthermore, the polarity of regulation may be changed during operation of the flux pump by controlling the phase offset.

While the foregoing example is described in relation to waveform polarity regulation, this should not be seen as limiting, and any desirable characteristic of the waveform may be selectively targeted by adjusting the phase relationship as described herein. For example, in other forms, the phase delay may be configured to selectively transfer to the load any one or more of: the peak induced current, induced currents which exceed a predetermined threshold, and/or frequency characteristics of the induced waveform.

In another form of the technology, by adjusting the relative dimensions of the induction coil 310, switch 312, and magnetic field generators 306, it is possible to adjust how long magnetic field generator acts upon the induction coil 310 and switch 312. For example, a larger magnetic field generator may be able to hold the switch 312 in the higher-resistance state for a longer duration, and therefore change the optimal phase relationship between the induction coil and the switch.

FIG. 12D shows test results from an example of the technology which has been configured such that the peak current induced in the load occurs with a substantially zero-degree phase offset between the activation of the switch 312 and induction coil 310. Or more generally, the optimal phase offset between the switch 312 and the induction coil 310 may be between approximately −10 and approximately 5 degrees. Data from FIG. 12D is summarised in the following table:

TABLE 2
Alternative Example of Rotational Speed, Direction,
and Phase Offset Effects on Maximum Current

| | Angle | | | | | | |
|---|---|---|---|---|---|---|---|
| RPM | −10 | −5 | 0 | 5 | 10 | 15 | 25 |
| 50 | 10.3 | 10.0 | 10.2 | 8.5 | 6.5 | 4.0 | −0.1 |
| 100 | 11.3 | 11.0 | 11.5 | 10.1 | 8.7 | 6.5 | 2.7 |
| 150 | 11.8 | 11.6 | 12.2 | 10.9 | 9.8 | 7.7 | 4.3 |
| 200 | 12.1 | 12.0 | 12.6 | 11.5 | 10.5 | 8.4 | 5.3 |
| 250 | 12.3 | 12.2 | 12.7 | 11.8 | 10.9 | 8.9 | 6.0 |
| 300 | 12.2 | 12.3 | 12.8 | 12 | 11.2 | 9.4 | 6.5 |
| 350 | 12.3 | 12.3 | 12.9 | 12.2 | 11.4 | 9.6 | 6.9 |
| 400 | 12.2 | 12.5 | 12.8 | 12.3 | 11.6 | 9.9 | 7.3 |
| 450 | 11.5 | 12.4 | 12.8 | 12.3 | 11.8 | 10.0 | 7.7 |

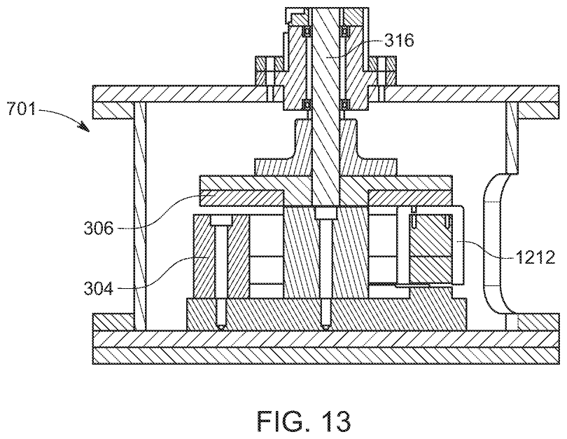

According to one form of the technology shown in FIG. 13, there is provided a flux pump comprising a rotor 302 and stator 304 positioned within a housing 701. In this example the housing 701 comprises a bearing group which in use supports the shaft 316. In this example a first stator arm 320A comprises the induction coil 310, while the opposing stator arm 320B comprises a switch holder 1212 which allows for adjustment of the switch 312 positioning relative to the induction coil 310.

### 6.6.5. Induced Current Frequency

From the graph of FIG. 12C is can also be seen that, in one experimental example, peak induced current was found at approximately 150 RPM when the flux pump was running in a first direction and approximately 125 RPM when the flux pump was operated in a second, reverse direction. It is believed that these differences are due to the asymmetric nature of the test configuration as previously discussed.

Accordingly, the phase offsets described herein may be represented as time offsets for a given rotational speed and/or number of magnetic field generators 306 positioned on the rotor 302.

It should also be appreciated that the optimal rotational speeds identified in the experiments performed were with a rotor 302 having two magnetic field generators 306. However, this should not be seen as limiting on the technology, for example, in forms of the technology comprising a single magnetic field generator, the speeds which induced the peak currents may be expected to be between approximately 250 RPM and 300 RPM. Similarly, in examples of the technology which use more magnetic field generators 306 such as 4, 6 or 8 generators, a corresponding reduction in RPM may be expected in order to obtain a peak induced current.

### 6.7. Bifilar Switch Configuration

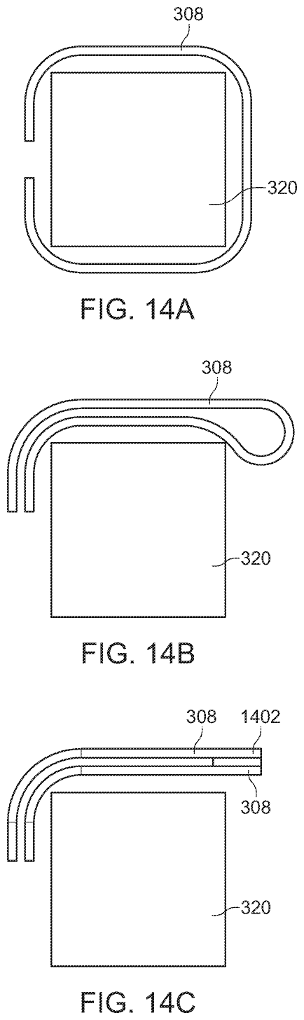

One example of a J_{c}(B) switch 312 in accordance with the present technology is shown in FIG. 14A. In this example, the one or more lengths of superconducting material 308 is looped around a stator arm 320, such as using a switch holder as discussed in relation to FIGS. 12A and 12B. In other words, in one aspect of the technology, the switch may comprise one or more lengths of superconducting material 308, provided in a loop around a stator arm.

In another aspect of the technology, a switch 312 may be provided by looping one or more lengths of superconducting material 308 onto itself to provide a bifilar arrangement.

In the context of this specification, unless otherwise stated, a “bifilar arrangement” should be understood to mean an arrangement of two strands of a conductor in which the two strands of the conductor are substantially parallel and electrically connected so that current flows through the strands in opposite directions. The strands may be closely adjacent to each other. The strands may be two sections of a length of superconducting material that is doubled back on itself. Alternatively, the two strands may be separate lengths of superconducting material that are electrically connected together, for example by soldering, diffusion joint or other suitable form of electrical connection.

The bifilar arrangements described herein may be positioned on or adjacent to a ferromagnetic member such as a stator arm, so as to couple the magnetic field from the magnetic field generator through the one or more lengths of superconducting material. In some aspects of the technology the bifilar arrangement may be provided between a field spreader and stator arm as described herein.

One potential advantage of the bifilar configuration is the ability to reduce the loop area of the superconducting material 308 and therefore reduce the inductance in comparison to the loop arrangement of FIG. 14A. Furthermore, this arrangement reduces the self-field effect of the switch 312 as the fields generated on each side of the bifilar arrangement cancel each other out.

This bifilar configuration allows for the switch 312 to generate a voltage without inducing any current. For comparison dynamo flux pumps are known to use a single HTS tape which induces current and produces a voltage. Other potential advantages of the bifilar construction include reduced inductance of the switch 312 when compared to a similar switch with a single length of superconducting material.

Another benefit of a switch 312 comprising a bifilar arrangement of a length of superconducting material is that it assists in reducing suppression of the critical current of the length of superconducting material when the magnetic field applied to the length of superconducting material is low, for example zero. This leads to a higher critical current for the low-resistance state of the switch 312.

In another form of the technology shown in FIG. 14C a bifilar switch is provided in which two superconducting material 308 layers are layered on top of one another and joined by a joint such as a normally conducting or solder joint 1402. This arrangement may advantageously further reduce the loop inductance, as well as accounting for any minimum bend radius issues which may present with a single length of superconducting material such as the examples shown in FIGS. 14A and 14B.

Further examples and applications of bifilar switch configurations using superconducting materials are provided in PCT application No. PCT/NZ2022/050009, the entire contents of which is herein incorporated by reference in its entirety.

### 6.8. Experimental Data

FIG. 15 shows an example of the present technology in use, wherein the optical trigger was not used in the graph shown, but can be used experimentally to determine the point at which the magnetic field generator 306 is in alignment with the induction coil 310. Vjoint represents the voltage drop across the series shunt resistance, Vcoil is the induced voltage in the induction coil 310, and Vbridge shows the voltage across the switch 312. Note that the phase offset from the optical trigger means that the switch 312 is activated at the approximate peak of the voltage induced in the induction coil 310.

Vload is a measurement of the voltage across the load 314, while Vhall is a measurement of the magnetic field within the load 314. Note that the load 314 field remains positive and is increased slightly on a cycle-by-cycle basis.

In general terms, rotation of the one or more magnetic field generators 306 relative to the induction coil 310, results in current flow in the induction coil. This current flow begins before the magnet has passed the induction coil, and has a peak induced current shortly thereafter (represented by the peak voltage of approximately 1.9 mV). This current has a large positive component, before swinging negative, and decaying over time.

Shortly after the peak current is observed in the induction coil 310, (for example approximately 0.01 seconds after) a peak voltage across the switch 312 is observed (Vbridge reaching 0.5 mV, in the graph). This corresponds to the at least one magnetic field generator 306 reducing the critical current of the switch 312, and therefore transitioning the switch 312 from the low-resistance state to the higher resistance state.

In the example shown, the total period of the waveforms is approximately 0.2 seconds, and therefore the 0.01 second delay between the peak current in the induction coil, and peak voltage across the switch corresponds to an approximate 5% delay or 18-degree phase offset between the induction coil and switch.

The increase in switch resistance corresponds to an increase in the voltage across the load, which can be seen to be decaying prior to the switch resistance increasing. This results in an observable increase in the voltage measured by a Hall-effect sensor (Vhall) which is indicative of the current in the load. Accordingly, the activation of the switch in a synchronised manner in relation to the peak current induced in the induction coil, provides a net-DC rectified load 314 current.

### 6.9. Other Remarks

Unless the context clearly requires otherwise, throughout the description and the claims, the words “comprise”, “comprising”, and the like, are to be construed in an inclusive sense as opposed to an exclusive or exhaustive sense, that is to say, in the sense of “including, but not limited to”.

The entire disclosures of all applications, patents and publications cited above and below, if any, are herein incorporated by reference.

Reference to any prior art in this specification is not, and should not be taken as, an acknowledgement or any form of suggestion that that prior art forms part of the common general knowledge in the field of endeavour in any country in the world.

The technology may also be said broadly to consist in the parts, elements and features referred to or indicated in the specification of the application, individually or collectively, in any or all combinations of two or more of said parts, elements or features.

Where in the foregoing description reference has been made to integers or components having known equivalents thereof, those integers are herein incorporated as if individually set forth.

It should be noted that various changes and modifications to the presently preferred embodiments described herein will be apparent to those skilled in the art. Such changes and modifications may be made without departing from the spirit and scope of the technology and without diminishing its attendant advantages. It is therefore intended that such changes and modifications be included within the present technology.

1. A device for inducing a current flow in a load, comprising:
a rotor which comprises at least one magnetic field generator configured to rotate with the rotor, wherein the at least one magnetic field generator generates a magnetic field, and
one or more lengths of superconducting material arranged to provide an induction coil, a switch, and two or more output terminals configured to connect to the load in use, the two or more output terminals being electrically connected in parallel with the switch,
wherein rotation of the rotor moves the at least one magnetic field generator relative to the induction coil and switch, such that:
the magnetic field is periodically applied to the induction coil to induce a current flow in the induction coil, at least part of the current flow being configured to flow through the switch, and
the magnetic field is periodically applied to the switch and reduces a critical current of the superconducting material within the switch, such that the magnetic field and the current flow within the switch cause the switch to transition from a low-resistance state to a higher-resistance state.

2. A device for inducing a current flow in a load, comprising:
a rotor which comprises at least one magnetic field generator configured to rotate with the rotor, wherein the at least one magnetic field generator generates a magnetic field, and
a stator,
wherein the stator is provided with one or more lengths of superconducting material arranged to provide an induction coil, and a switch, and two or more output terminals configured to connect to the load in use, the two or more output terminals being electrically connected in parallel with the switch,
wherein in use the rotor is configured to rotate relative to the stator, and the at least one magnetic field generator is configured to periodically apply the magnetic field:
to the induction coil to induce a current flow in the induction coil, and
to the switch to transition the switch between a low-resistance state and a higher-resistance state for a given current flow within the switch.

3. (canceled)

4. The device of claim 1, wherein the magnetic field generated by the magnetic field generator is applied to the switch such that a component of the magnetic field is applied in a direction perpendicular to a surface of the switch.

5. The device of claim 1, wherein the rotor comprises a drive shaft, and wherein the longitudinal axis of the drive shaft defines a rotational axis about which the rotor rotates in use.

6. The device of claim 5, wherein the at least one magnetic field generator is positioned radially outwardly of the rotational axis.

7. The device of claim 1, wherein the rotor is configured to provide a high magnetic permeability pathway for the magnetic field generated by the magnetic field generator.

8. The device of claim 1, wherein the rotor comprises a ferromagnetic material.

9. The device of claim 1, wherein the rotor comprises a plurality of magnetic field generators.

10. The device of claim 9, wherein each of the plurality of magnetic field generators are positioned at substantially the same radial distance from a rotational axis of the rotor as each other.

11. The device of claim 10, wherein the plurality of magnetic field generators are substantially evenly distributed around the rotational axis, such that the angle between each of the plurality of magnetic field generators is substantially the same, when measured relative to the rotational axis.

12. The device of claim 1, wherein the at least one magnetic field generator is positioned at a radial distance from a rotational axis of the rotor which is substantially the same as the radial distance of the switch from the rotational axis.

13. The device of claim 1, wherein the at least one magnetic field generator is positioned on a side of the rotor which is closest to the induction coil, and switch.

14. The device of claim 1, wherein the induction coil, switch and two or more output terminals are provided on a stator.

15. The device of claim 2, wherein the stator is configured to provide a high magnetic permeability pathway for the magnetic field generated by the magnetic field generator.

16. (canceled)

17. The device of claim 1, wherein the switch is positioned between approximately 167 and approximately 193 degrees relative to the induction coil, when measured about a rotational axis of the rotor.

18. (canceled)

19. (canceled)

20. The device of claim 1, wherein the magnetic field generator comprises a permanent magnet.

21. The device of claim 1, wherein the magnetic field generator comprises an electromagnet.

22. The device of claim 1, further comprising a field spreader, wherein the field spreader is configured to create a homogenous magnetic field in the at least one length of superconducting material of the switch.

23. The device of claim 1, wherein the switch and induction coil are positioned within a cryostat.

24. A rectifier comprising:
a rotor which comprises at least one magnetic field generator configured to rotate with the rotor, wherein the at least one magnetic field generator generates a magnetic field,
an induction coil, and
a switch comprising one or more lengths of superconducting material,
wherein, in use the rectifier is configured to connect to a load, the load being connected electrically in parallel with the switch,
wherein in use the rotor is configured to rotate to move the at least one magnetic field generator relative to the induction coil and switch, to periodically apply the magnetic field to the induction coil and switch such that:
a current flow is induced in the induction coil, the current flow having a positive component and a negative component over time, wherein at least part of the current flow is configured to flow through the switch, and the load, and
the magnetic field applied to the switch reduces a critical current of the superconducting material within the switch, such that the magnetic field and the current flow within the switch cause the switch to transition from a low-resistance state to a higher-resistance state,
wherein the application of the magnetic field to the switch is synchronised with the positive or negative component of the current flow, such that the switch transitions to the higher-resistance state to increase the amount of current flowing in the load during the positive or negative component, thereby providing a net positive or negative current flow in the load.

25. (canceled)
